(19) United States
(12) Patent Application Publication
(10) Pub. No.: US 2026/0090412 A1
(43) Pub. Date: Mar. 26, 2026

(54) WIRING SUBSTRATE AND SEMICONDUCTOR DEVICE

(71) Applicant: SHINKO ELECTRIC INDUSTRIES CO., LTD., Nagano-shi (JP)

(72) Inventor: Toyoaki SAKAI, Nagano-shi (JP)

(21) Appl. No.: 19/321,903

(22) Filed: Sep. 8, 2025

(30) Foreign Application Priority Data
Sep. 20, 2024 (JP) 2024-164370

(51) Int. Cl. H01L 23/538; H01L 23/00; H01L 25/16

(52) U.S. Cl. CPC H10W 70/614; H10W 70/611; H10W 70/65; H10W 90/00; H10W 90/401; H10W 74/15; H10W 90/724; H10W 90/733; H10W 90/734

(57) ABSTRACT

A wiring substrate includes a first insulating layer, a first wiring layer formed on the first insulating layer, an N number of insulating layers formed on the first insulating layer and covering the first wiring layer, a cavity formed in the N number of insulating layers and exposing part of the first insulating layer, an electronic component disposed in the cavity and including an electrode covered by the first insulating layer, a filling insulating layer covering the electronic component in the cavity, first via wiring extending through the first insulating layer and connected to the electrode, and a second wiring layer formed on the first insulating layer and electrically connected by the first via wiring to the electrode. The cavity has an opening width that decreases toward the first insulating layer, and the first via wiring has a diameter that decreases toward the electronic component.

### CROSS-REFERENCE TO RELATED APPLICATIONS

This application is based upon and claims the benefit of priority from prior Japanese Patent Application No. 2024-164370, filed on Sep. 20, 2024, the entire contents of which are incorporated herein by reference.

### BACKGROUND

### 1. Field

The present disclosure relates to a wiring substrate, a semiconductor device, and a method for manufacturing a wiring substrate.

### 2. Description of Related Art

A wiring substrate may incorporate an electronic component (refer to JP2022-80677A). Such a wiring substrate may include insulating layers, a cavity formed in the insulating layers, and a conductive pad exposed from the bottom of the cavity. An electronic component is mounted on the conductive pad. The cavity is filled with a filling insulating layer to cover the electronic component. The wiring substrate may be manufactured, for example, in the following manner. First, the conductive pad is formed and covered by a protective material. Then, a stack of the insulating layers is formed so as to cover the conductive pad and the protective material. A given region of the insulating layers is removed to form a cavity exposing the protective material. Then, the protective material is removed to expose the conductive pad. The electronic component is mounted on the conductive pad. Then, the cavity is filled with the filling insulating layer to cover the electronic component.

### SUMMARY

It is desirable that the cost for manufacturing such a wiring substrate be reduced.

In one general aspect, a wiring substrate of a coreless type includes a first insulating layer, a first wiring layer formed on the first insulating layer, an N number (where N is a natural number greater than or equal to 1) of insulating layers formed on a first surface of the first insulating layer and including a second insulating layer that covers the first wiring layer, a cavity formed in the N number of insulating layers and exposing a part of the first surface of the first insulating layer, an electronic component disposed in the cavity and including a first electrode covered by the first insulating layer, a filling insulating layer with which the cavity is filled covering the electronic component, first via wiring extending through the first insulating layer in a thickness direction and connected to the first electrode, and a second wiring layer formed on a second surface of the first insulating layer opposite the first surface and electrically connected by the first via wiring to the first electrode. The cavity has an opening width that decreases toward the first insulating layer, and the first via wiring has a diameter that decreases toward the electronic component.

Other features and aspects will be apparent from the following detailed description, the drawings, and the claims.

### BRIEF DESCRIPTION OF THE DRAWINGS

FIG. 1 is a schematic cross-sectional view illustrating a wiring substrate in accordance with a first embodiment.

FIG. 2 is a schematic cross-sectional view illustrating, in an enlarged manner, part of the wiring substrate in accordance with the first embodiment.

FIG. 3 is a schematic cross-sectional view illustrating a semiconductor device in accordance with the first embodiment.

FIGS. 4, 5, 6, 7, 8, 9, 10, 11, 12, 13, 14, 15, 16, 17, 18, 19, 20, 21, 22, 23, 24, 25, and 26 are schematic cross-sectional views illustrating the procedures of a method for manufacturing the semiconductor device in accordance with the first embodiment.

FIG. 27 is a schematic cross-sectional view illustrating a wiring substrate in accordance with a second embodiment.

FIG. 28 is a schematic cross-sectional view illustrating, in an enlarged manner, part of a wiring substrate in accordance with the second embodiment.

FIGS. 29, 30, 31, 32, 33, 34, 35, 36, 37, 38, and 39 are schematic cross-sectional views illustrating the procedures of a method for manufacturing the wiring substrate in accordance with the second embodiment.

FIG. 40 is a schematic cross-sectional view illustrating a wiring substrate in accordance with a third embodiment.

FIGS. 41, 42, 43, 44, and 45 are schematic cross-sectional views illustrating the procedures of a method for manufacturing the wiring substrate in accordance with the third embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

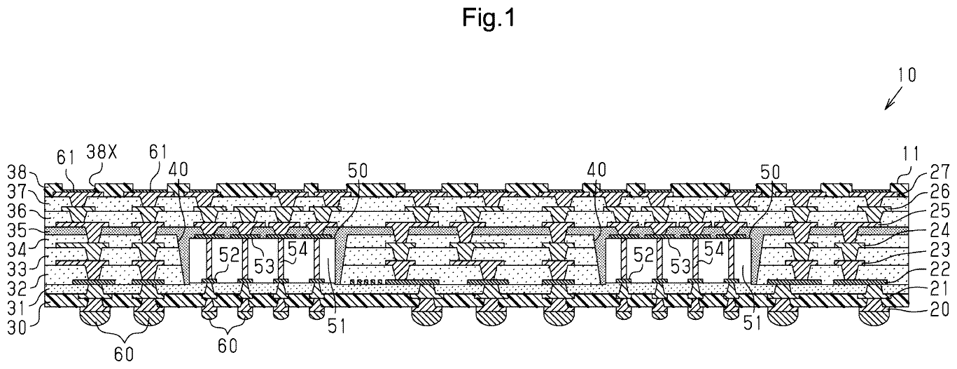

Embodiments will now be described with reference to the drawings. In the accompanying drawings, elements are illustrated for simplicity and clarity and have not necessarily been drawn to scale. In the cross-sectional views, to facilitate understanding of the cross-sectional structure of each member, hatching lines may be replaced by shadings or may not be illustrated. In this specification, a plan view refers to a view of a subject taken in a vertical direction (e.g., vertical direction as viewed in FIG. 1), and a planar shape refers to a shape of a subject as viewed in the vertical direction. Further, in this specification, upward, downward, leftward, and rightward directions refer to directions that allow for the reference characters denoting members to be read properly. In this specification, diameter refers to a distance between two points that are farthest from each other in a cross section extending in the horizontal direction of a subject (sideward direction in each drawing). That is, for example, when the cross section is circular, diameter refers to the diameter of the circle. When the cross section is polygonal, diameter refers to the length of the longest diagonal line in the polygon. When the cross section is elliptical, the diameter refers to the major axis of the ellipse Also, in this specification, the term face is used to indicate that surfaces or members are arranged in front of each other. In this case, the surfaces or members do not have to be entirely in front of each other and may be partially in front of each other. Moreover, in this specification, the term face will also be used to describe situations including a case in which two members are separated from each other and a case in which two members are in contact with each other. In the description of the present disclosure, a numerical range of “X1 to X2,” which is specified by the lower limit value X1 and the upper limit value X2, refers to a range that is greater than or equal to X1 and less than or equal to X2, unless otherwise specified.

### First Embodiment

A first embodiment will now be described with reference to FIGS. 1 to 26.

### Overall Structure of Wiring Substrate 10

With reference to FIG. 1, a wiring substrate 10 includes a wiring structure 11, one or more (two, in the present embodiment) cavities 40 formed in the wiring structure 11, and one or more (two, in the present embodiment) electronic components 50 disposed in the cavities 40. The wiring substrate 10 incorporates the electronic components 50.

### Structure of the Electronic Component 50

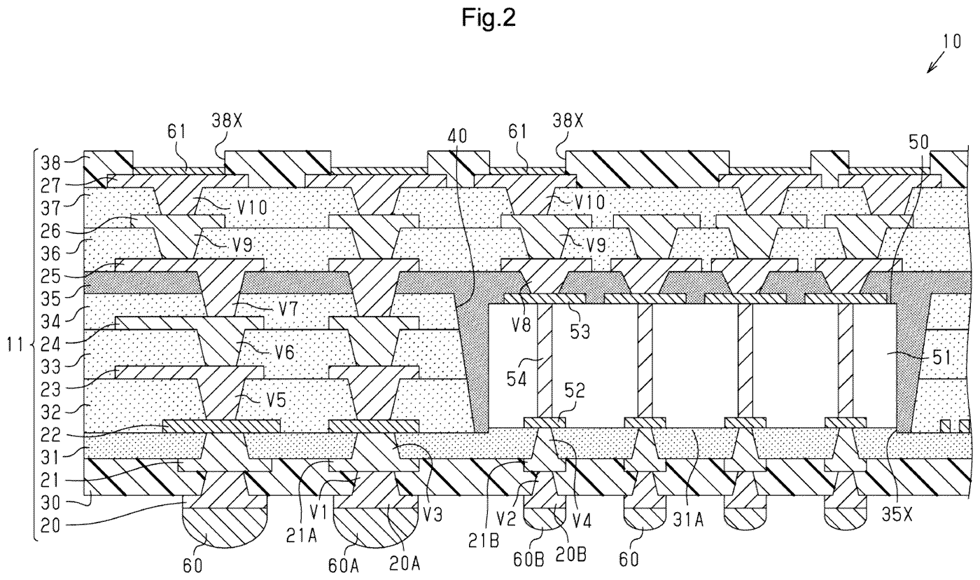

With reference to FIG. 2, each electronic component 50 includes a main body 51, first electrodes 52 arranged in the lower portion of the electronic component 50, third electrodes 53 arranged on the upper portion of the electronic component 50, and through-electrodes 54. The electronic component 50 of the present embodiment includes the first electrodes 52, the third electrodes 53, and the through-electrodes 54.

The electronic component 50 may be, for example, a semiconductor element, a quartz oscillator, a chip component, or a silicon bridge. Examples of a chip component include a chip capacitor, a chip resistor, and a chip inductor. Further, the electronic component 50 may be a wiring structural body formed by an organic resin. The electronic components 50 incorporated in the wiring substrate 10 do not have to be of a single type and may be of more than one type.

The main body 51 is, for example, box-shaped. The main body 51 may have a thickness of, for example, approximately 50 μm to 200 μm. The main body 51 is formed from, for example, silicon (Si) or silicon carbide (SIC).

The material of the first electrodes 52, the third electrodes 53 and the through-electrodes 54 may be, for example, a metal such as aluminum (Al) or copper (Cu) or an alloy including at least one of these metals.

Each first electrode 52 is, for example, embedded in the main body 51. The lower surface of the first electrode 52 is exposed from the lower surface of the main body 51. Further, the lower surface of the first electrode 52 is, for example, flush with the lower surface of the main body 51. The first electrode 52 may have a thickness of, for example, approximately 2 μm to 20 μm. The first electrode 52 may project downward from the lower surface of the main body 51.

The third electrodes 53 are arranged on the main body 51 at the opposite side of the first electrodes 52. The third electrodes 53, for example, project upward from the upper surface of the main body 51. The third electrodes 53 may each have a thickness of, for example, approximately 2 μm to 20 μm. The third electrodes 53 may be embedded in the main body 51.

The through-electrodes 54 extend through the main body 51 in a thickness direction. The through-electrodes 54, for example, extend straight in the thickness direction of the main body 51. The through-electrodes 54 electrically connect the first electrodes 52 to the third electrodes 53.

### Construction of the Wiring Structure 11

The wiring structure 11 is constructed by sequentially stacking a wiring layer 20, a solder resist layer 30, a wiring layer 21, an insulating layer 31, a wiring layer 22, an insulating layer 32, a wiring layer 23, an insulating layer 33, a wiring layer 24, an insulating layer 34, an insulating layer 35, a wiring layer 25, an insulating layer 36, a wiring layer 26, an insulating layer 37, a wiring layer 27, and a solder resist layer 38. The wiring substrate 10 of the present embodiment is a coreless substrate that does not include a support base and thus differs from a wiring substrate manufactured through a typical build-up process, that is, a wiring substrate formed by sequentially stacking a given number of build-up layers on one side or two opposite sides of a core substrate serving as a support base. In the present embodiment, for the sake of simplicity, as viewed in FIG. 2, the side of the wiring substrate 10 where the solder resist layer 30 is located will be referred to as the lower side or one side, and the side of the wiring substrate 10 where the solder resist layer 38 is located will be referred to as the upper side or the other side. Further, in the present embodiment, for the sake of simplicity, the surface of each portion located toward the solder resist layer 30 will be referred to as one surface or the lower surface, and the surface of each portion located toward the solder resist layer 38 will be referred to as the other surface of the upper surface. The wiring substrate 10 may be used in a state reversed upside down or be arranged at any angle.

The material of the wiring layers 20, 21, 22, 23, 24, 25, 26, and 27 may be, for example, copper or a copper alloy. The wiring layers 20, 21, 22, 23, 24, 25, 26, and 27 may each have a thickness of, for example, approximately 1 μm to 35 μm. The wiring layers 20, 21, and 22 have, for example, a smaller line/space (L/S) than the wiring layers 23, 24, 25, 26, and 27. The line/space of the wiring layers 20, 21, and 22 may be, for example, approximately 2 μm/2 μm to 3 μm/3 μm. The line/space of the wiring layers 23, 24, 25, 26, and 27 may be, for example, approximately 3 μm/3 μm to 50 μm/50 μm. In the term line/space, line represents the width of a line, and space represents the distance between adjacent lines (interline distance). For example, when the line/space is 10 μm/10 μm to 50 μm/50 μm, the line width is greater than or equal to 10 μm and less than or equal to 50 μm. Further, the interline distance between adjacent lines is greater than or equal to 10 μm and less than or equal to 50 μm. The line width does not necessarily have to be equal to the interline distance.

The insulating layers 31, 32, 33, 34, 35, 36, and 37 may be formed from, for example, a material of which the main component is a non-photosensitive resin. The insulating layers 31, 32, 33, 34, 35, 36, and 37 may be formed from, for example, a material of which the main component is a thermosetting and non-photosensitive resin, such as an epoxy resin, an imide resin, a phenol resin, or a cyanate resin. The solder resist layers 30 and 38 may be formed from, for example, a material of which the main component is a photosensitive resin. The solder resist layers 30 and 38 may be formed from, for example, a photosensitive insulative resin of which the main component is a phenol resin or a polyimide resin.

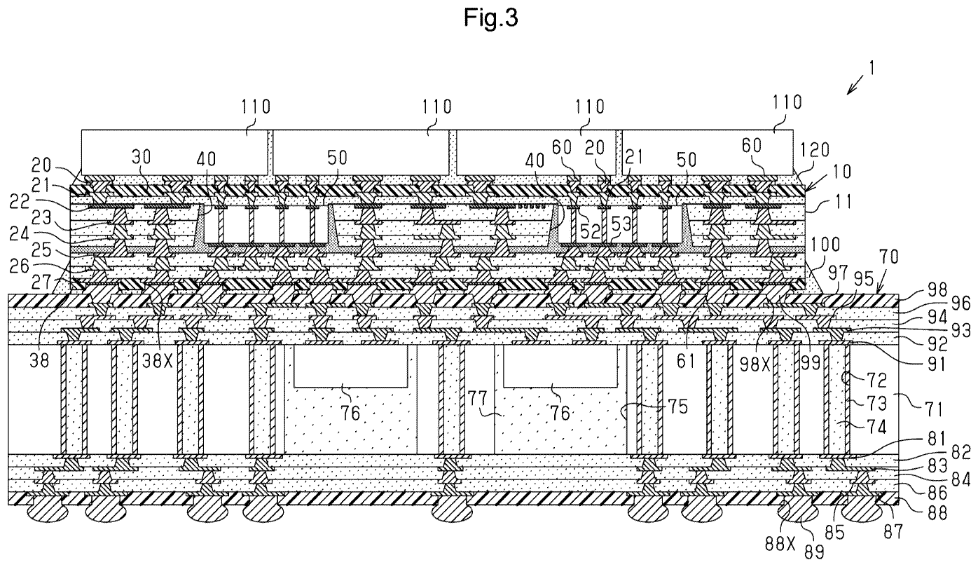

The wiring layer 20 is formed on the lower surface of the solder resist layer 30. The wiring layer 20 projects downward from the lower surface of the solder resist layer 30. The wiring layer 20 is, for example, the outermost layer (here, the lowermost layer) of the wiring substrate 10. The wiring layer 20 has, for example, the functionality of a chip mounting pad electrically connected to semiconductor chips 110 (refer to FIG. 3). The surface of the wiring layer 20 acts as a chip mounting surface.

The wiring layer 20 includes a wiring layer 20A and a wiring layer 20B. The wiring layer 20A is electrically connected to the wiring layer 21 by via wiring V1 extending through the solder resist layer 30 in the thickness direction. The wiring layer 20A is, for example, formed integrally with the via wiring V1. The wiring layer 20A and the via wiring V1 are, for example, located at positions separated from the electronic components 50 in plan view. The wiring layer 20B is electrically connected to the wiring layer 21 by via wiring V2 extending through the solder resist layer 30 in plan view. The wiring layer 20B is, for example, formed integrally with the via wiring V2. The wiring layer 20B and the via wiring V2 are, for example, located at positions overlapping the electronic components 50 in plan view.

The via wiring V2 has a smaller diameter than the via wiring V1. The diameter of the via wiring V1 may be, for example, approximately 20 μm to 100 μm. The diameter of the via wiring V2 may be, for example, approximately 3 μm to 30 μm.

A surface-processed layer may be formed on the surface (lower surface and side surfaces or only lower surface) of the wiring layer 20 when necessary. The surface-processed layer may be a Au layer, a Ni layer/Au layer (metal layer formed by laminating a Ni layer and a Au layer in this order), or a Ni layer/Pd layer/Au layer (metal layer formed by laminating a Ni layer, a Pd layer, and a Au layer in this order). Further, the surface-processed layer may by a Ni layer/Sn layer (metal layer formed by laminating a Ni layer and a Sn layer in this order), Ni layer/Sn layer/In layer (metal layer formed by laminating a Ni layer, a Sn layer, and an In layer in this order), a Bi layer, or the like. An Au layer is a metal layer formed from Au or an Au alloy, a Ni layer is a metal layer formed from Ni or a Ni alloy, and a Pd layer is a metal layer formed from Pd or a Pd alloy. Further, a Sn layer is a metal layer formed from Sn or a Sn alloys, an In layer is a metal layer formed from In or an In alloy, and a Bi layer is a metal layer formed from Bi or a Bi alloy. The Au layer, the Ni layer, the Pd layer, the Sn layer, the In layer, and the Bi layer may each be, for example, a metal layer formed through an electroless plating process (electroless plating metal layer) or a metal layer formed through an electrolytic plating process (electrolytic plating metal layer). The surface-processed layer may be an organic solderability preservative (OSP) film formed on the surface of the wiring layer 20 through an anti-oxidation process such as an OSP process. The OSP film may be, for example, an organic coating of an azole compound or an imidazole compound.

External connection terminals 60 are arranged on, for example, the lower surface of the wiring layer 20. The external connection terminals 60 may be, for example, solder balls. The material of the solder balls may be, for example, Pb-free solder of Sn—Ag, Sn—Cu, or Sn—Ag—Cu The external connection terminals 60 includes external connection terminals 60A, which are defined by the lower surface of the wiring layer 20A, and external connection terminals 60B, which are defined by the lower surface of the wiring layer 20B. The external connection terminals 60B have a smaller diameter than the external connection terminals 60A. The external connection terminals 60B are arranged at a smaller pitch than the external connection terminals 60A. The pitch of the external connection terminals 60A is, for example, approximately 60 μm to 150 μm. The pitch of the external connection terminals 60B is, for example, approximately 10 μm to 100 μm.

The solder resist layer 30 is formed on the lower surface of the insulating layer 31 and covers the wiring layer 21. The solder resist layer 30 covers the lower surface and the side surfaces of the wiring layer 21. The solder resist layer 30 covers the upper surface of the wiring layer 20. The thickness from the lower surface of the wiring layer 21 to the lower surface of the solder resist layer 30 may be, for example, approximately 12 μm to 50 μm.

The wiring layer 21 is formed on the lower surface (second surface) of the insulating layer 31. The wiring layer 21 includes a wiring layer 21A and a wiring layer 21B. The wiring layer 21A is electrically connected to the wiring layer 22 by via wiring V3 extending through the insulating layer 31 in the thickness direction. The wiring layer 21A is, for example, formed integrally with the via wiring V3. The wiring layer 21A is electrically connected by the via wiring V1 to the wiring layer 20A. The wiring layer 21A and the via wiring V3 are, for example, located at positions separated from the electronic components 50 in plan view. The wiring layer 21B is electrically connected to the first electrodes 52 of the electronic components 50 by via wiring V4 extending through the insulating layer 31 in the thickness direction. The wiring layer 21B is, for example, formed integrally with the via wiring V4. The wiring layer 21B is electrically connected by the via wiring V2 to the wiring layer 20B. The wiring layer 21B and the via wiring V4 are, for example, located at positions overlapping the electronic components 50 in plan view.

The via wiring V4 has a smaller diameter than the via wiring V3. The diameter of the via wiring V3 may be, for example, approximately 20 μm to 100 μm. The diameter of the via wiring V4 may be, for example, approximately 3 μm to 30 μm.

The via wiring V1, V2, V3, and V4 is, for example, tapered so that its diameter decreases from the lower side (side located toward solder resist layer 30) toward the upper side (side located toward wiring layer 22 or first electrodes 52), as viewed in FIG. 2. The via wiring V1, V2, V3, and V4 has the form of a truncated cone of which the diameter at the upper surface is less than that at the lower surface.

The insulating layer 31 is formed on the lower surface of the insulating layer 32 and covers the wiring layer 22. The insulating layer 31 covers the lower surface of the wiring layer 22. The insulating layer 31 is formed on the upper surface of the solder resist layer 30 and covers the upper surface of the wiring layer 21. The insulating layer 31 includes projections 31A projecting from the upper surface of the insulating layer 31 into the cavities 40. The insulating layer 31 is a single layer. The projections 31A are located within the cavities 40. The projections 31A overlap the electronic components 50 in plan view. The projections 31A cover the lower surface of the electronic components 50. The projections 31A cover the lower surface of each main body 51 and covers the lower surfaces of the first electrodes 52. The projections 31A may each have a thickness of, for example, approximately 0.1 μm to 25 μm. The thickness from the lower surface of the wiring layer 22 to the lower surface of the insulating layer 31 is, for example, approximately 5 μm to 40 μm.

The wiring layer 22 is formed on the upper surface (first surface) of the insulating layer 31. The lower surface of the wiring layer 22 is exposed from the lower surface of the insulating layer 32. The lower surface of the wiring layer 22 is, for example, flush with the lower surface of the insulating layer 32.

The insulating layer 32 is formed on the upper surface (first surface) of the insulating layer 31 and covers the wiring layer 22. The insulating layer 32 covers the upper surface and the side surfaces of the wiring layer 22. The thickness from the upper surface of the wiring layer 22 to the upper surface of the insulating layer 32 is, for example, approximately 15 μm to 60 μm.

The wiring layer 23 is formed on the upper surface of the insulating layer 32. The wiring layer 23 is electrically connected to the wiring layer 22 by the via wiring V5 extending through the insulating layer 32 in the thickness direction. The wiring layer 23 is, for example, formed integrally with the via wiring V5. The wiring layer 23 is located at positions separated from the cavities 40 in plan view.

The insulating layer 33 is formed on the upper surface of the insulating layer 32 and covers the wiring layer 23. The insulating layer 33 covers the upper surface and the side surfaces of the wiring layer 23. The thickness from the upper surface of the wiring layer 23 to the upper surface of the insulating layer 33 is, for example, approximately 15 μm to 60 μm.

The wiring layer 24 is formed on the upper surface of the insulating layer 33. The wiring layer 24 is electrically connected to the wiring layer 23 by via wiring V6 extending through the insulating layer 33 in the thickness direction. The wiring layer 24 is, for example, formed integrally with the via wiring V6. The wiring layer 24 is located at positions separated from the cavities 40 in plan view.

The insulating layer 34 is formed on the upper surface of the insulating layer 33 and covers the wiring layer 24. The insulating layer 34 covers the upper surface and the side surfaces of the wiring layer 24. The thickness from the upper surface of the wiring layer 24 to the upper surface of the insulating layer 34 is, for example, approximately 10 μm to 40 μm.

The cavities 40 are each formed in the insulating layers 32, 33, and 34. The cavities 40 are recessed downward from the upper surface of the insulating layer 34. The cavities 40 extend through the insulating layers 32, 33, and 34 in the thickness direction. Each cavity 40, for example, exposes a part of the upper surface of the insulating layer 31. The cavities 40 are formed in correspondence with the incorporated electronic components 50. That is, each cavity 40 is formed at a position where one of the electronic components 50 is mounted.

The cavities 40 are each, for example, tapered to have an opening width that decreases from the upper side (upper surface of insulating layer 34) toward the lower side (insulating layer 31), as viewed in FIG. 2. That is, the cavities 40 widen from the lower side toward the upper side. The space surrounded by the wall surfaces of each cavity 40, the upper surface of the insulating layer 31 exposed in the cavity 40 and the upper surfaces of the corresponding projection 31A, that is, the interior space of the cavity 40, defines an accommodation space for accommodating the corresponding electronic component 50. Accordingly, in the wiring substrate 10 of the present example, the three insulating layers 32, 33, and 34 act to construct a cavity-formation insulating layer.

The insulating layer 35 acts as a filling insulating layer with which the cavities 40 are filled. The cavities 40 are filled with the insulating layer 35 that covers the upper surface of the insulating layer 34 and covers the electronic components 50. The insulating layer 35 covers the wall surfaces of the cavities 40 entirely. The insulating layer 35, for example, covers each electronic component 50 entirely. For example, the insulating layer 35 covers the upper surface and the side surfaces of the main body 51. The insulating layer 35, for example, covers the upper surface and the side surfaces of each third electrode 53.

The lower surface of the insulating layer 35 in each cavity 40 includes, for example, a recess 35X. The recess 35X is recessed upward from the lower surface of the insulating layer 35. The recess 35X exposes the lower surface of the corresponding electronic component 50. The recess 35X is located at a position overlapping the corresponding electronic component 50 in plan view. The recess 35X is filled with, for example, the corresponding projection 31A of the insulating layer 31.

The insulating layer 35 covers, for example, the entire upper surface of the insulating layer 34. The thickness from the upper surface of the insulating layer 34 to the upper surface of the insulating layer 35 may be, for example, approximately 5 μm to 30 μm.

The wiring layer 25 is formed on the upper surface of the insulating layer 35. The wiring layer 25 is, for example, electrically connected to the wiring layer 24 by via wiring V7 extending through the insulating layers 34 and 35 in the thickness direction. The wiring layer 25 is electrically connected to the third electrodes 53 of the electronic components 50 by via wiring V8 extending through the insulating layer 35 in the thickness direction. The wiring layer 25 is, for example, formed integrally with the via wiring V7 and the via wiring V8. The wiring layer 25 may be laid out on the upper surface of the insulating layer 35 in a planar direction (i.e., direction orthogonal to stacking direction of wiring substrate 10). In the wiring layer 25, which is laid out in the planar direction, the parts of the wiring layer 25 connected to the wiring layer 24 may be electrically connected to the parts of the wiring layer 25 connected to the third electrodes 53.

The insulating layer 36 is formed on the upper surface of the insulating layer 35 and covers the wiring layer 25. The insulating layer 36 covers the upper surface and the side surfaces of the wiring layer 25. The thickness from the upper surface of the wiring layer 25 to the upper surface of the insulating layer 36 is, for example, approximately 15 μm to 60 μm.

The wiring layer 26 is formed on the upper surface of the insulating layer 36. The wiring layer 26 is electrically connected to the wiring layer 25 by via wiring V9 extending through the insulating layer 36 in the thickness direction. The wiring layer 26 is, for example, formed integrally with the via wiring V9.

The insulating layer 37 is formed on the upper surface of the insulating layer 36 and covers the wiring layer 26. The insulating layer 37 covers the upper surface and the side surfaces of the wiring layer 26. The thickness from the upper surface of the wiring layer 26 to the upper surface of the insulating layer 37 is, for example, approximately 15 μm to 60 μm.

The wiring layer 27 is formed on the upper surface of the insulating layer 37. The wiring layer 27 is electrically connected to the wiring layer 26 by via wiring V10 extending through the insulating layer 37 in the thickness direction. The wiring layer 27 is, for example, formed integrally with the via wiring V10. The wiring layer 27 is, for example, the outermost layer (here, the uppermost layer) of the wiring substrate 10.

The via wiring V5, V6, V7, V8, V9, and V10 is, for example, tapered so that its diameter decreases from the upper side (side located toward solder resist layer 38) toward the lower side (side located toward lower surface of insulating layer 32), as viewed in FIG. 2. The via wiring V5, V6, V7, V8, V9, and V10 has the form of an inverted truncated cone of which the diameter at the upper surface is greater than that at the lower surface. In this manner, the via wiring V5, V6, V7, V8, V9, and V10, formed upward from the wiring layer 22, has the form of an inverted truncated cone of which the diameter decreases toward the wiring layer 22. The via wiring V1, V2, V3, and V4, formed downward from the wiring layer 22, has the form of a truncated cone of which the diameter decreases toward the wiring layer 22. That is, the boundary where the via wiring V1, V2, V3, and V4 and the via wiring V5, V6, V7, V8, V9, and V10 change in structure is the wiring layer 22. Further, in the wiring structure 11, the stack structure of the wiring layers and insulating layers at the upper side of the wiring layer 22 differs from the stack structure of the wiring layers and insulating layers at the lower side of the wiring layer 22. Thus, the wiring layer 22 is the boundary where the stack structure changes. The diameter of the via wiring V2 and V4 is smaller than the diameter of the via wiring V1, V3, V5, V6, V7, V8, V9, and V10.

The solder resist layer 38 is formed on the upper surface of the insulating layer 37 and covers the wiring layer 27. The solder resist layer 38 covers the upper surface and the side surfaces of the wiring layer 27. The solder resist layer 38 is the outermost insulating layer (in this case, uppermost insulating layer) of the wiring substrate 10. The thickness from the upper surface of the wiring layer 27 to the upper surface of the solder resist layer 38 is, for example, approximately 12 μm to 50 μm.

The solder resist layer 38 includes openings 38X exposing parts of the upper surface of the wiring layer 27, which is the uppermost layer, as connection pads. A surface-processed layer 61 is formed on the parts of the wiring layer 27 exposed from the openings 38X. The surface-processed layer 61 may be an OSP film or a metal layer, such as a Au layer, a Ni layer/Au layer, or a Ni layer/Pd layer/Au layer.

### Structure of Semiconductor Device 1

The structure of a semiconductor device 1 will now be described with reference to FIG. 3.

The semiconductor device 1 includes a substrate 70, the wiring substrate 10 mounted on the substrate 70, an underfill resin 100, one or more (in the present embodiment, four) semiconductor chips 110 mounted on the wiring substrate 10, and an underfill resin 120. In FIG. 3 illustrates the wiring substrate 10 in a state rotated 180° from the state of FIGS. 1 and 2.

### Structure of the Substrate 70

The substrate 70 includes a core substrate 71. The core substrate 71 may be, for example, a glass epoxy substrate obtained by impregnating a glass cloth with a thermosetting insulative resin such as an epoxy resin. The core substrate 71 may be, for example, a substrate obtained by impregnating a woven cloth or non-woven cloth of glass fibers, carbon fibers, aramid fibers, or the like with a thermosetting insulative resin such as an epoxy resin. The drawings do not illustrate a glass cloth or the like.

The core substrate 71 includes through holes 72 extending through the core substrate 71 in the thickness direction. A through-electrode 73 extending through the core substrate 71 in the thickness direction is formed on the wall surface of each through holes 72. The central portion of each through hole 72, that is, the inner side of the through-electrode 73 in each through hole 72, is filled with a resin portion 74. The material of the through-electrode 73 may be, for example, copper or a copper alloy. The material of the resin portion 74 may be, for example, an insulative resin such as an epoxy resin.

The core substrate 71 includes one or more (in the present embodiment, two) openings 75 extending through the core substrate 71 in the thickness direction. An electronic component 76 is accommodated in each opening 75. The opening 75 is filled with a resin portion 77 that covers the electronic component 76. The resin portion 77 covers, for example, the lower surface and the side surfaces of the electronic component 76. The electronic component 76 may be, for example, a semiconductor element, a quartz oscillator, a chip component, or a silicon bridge. Examples of a chip component include a chip capacitor, a chip resistor, and a chip inductor. The electronic components 76 incorporated in the substrate 70 do not have to be of a single type and may be of more than one type. The material of the resin portion 77 may be, for example, an insulative resin such as an epoxy resin.

The substrate 70 includes a wiring structure formed by sequentially stacking a wiring layer 81, an insulating layer 82, a wiring layer 83, an insulating layer 84, a wiring layer 85, an insulating layer 86, a wiring layer 87, and a solder resist layer 88 on the lower surface of the core substrate 71. The substrate 70 also includes a wiring structure formed by sequentially stacking a wiring layer 91, an insulating layer 92, a wiring layer 93, an insulating layer 94, a wiring layer 95, an insulating layer 96, a wiring layer 97, and a solder resist layer 98 on the upper surface of the core substrate 71.

The material of the wiring layers 81, 83, 85, 87, 91, 93, 95, and 97 may be, for example, copper or a copper alloy. The wiring layers 81, 83, 85, 87, 91, 93, 95, and 97 may each have a thickness of, for example, approximately 8 μm to 40 μm. The insulating layers 82, 84, 86, 92, 94, and 96 may be formed from a material of which the main component is a non-photosensitive resin. The insulating layers 82, 84, 86, 92, 94, and 96 may be formed from, for example, a material of which the main component is a thermosetting and non-photosensitive resin, such as an epoxy resin, an imide resin, a phenol resin, or a cyanate resin. The insulating layers 82, 84, 86, 92, 94, and 96 may each have a thickness of, for example, approximately 15 μm to 100 μm. The solder resist layers 88 and 98 may be formed from a material of which the main component is a photosensitive resin. The solder resist layers 88 and 98 may be formed from, for example, a photosensitive insulative resin of which the main component is a phenol resin or a polyimide resin. The solder resist layers 88 and 98 may each have a thickness of, for example, approximately 12 μm to 50 μm.

The wiring layer 81 is formed on the lower surface of the core substrate 71. The wiring layer 81 is electrically connected to the through-electrodes 73. The insulating layer 82 is formed on the lower surface of the core substrate 71 and covers the wiring layer 81. The wiring layer 83 is formed on the lower surface of the insulating layer 82. The wiring layer 83 is electrically connected to the wiring layer 81 by via wiring extending through the insulating layer 82 in the thickness direction. The insulating layer 84 is formed on the lower surface of the insulating layer 82 and covers the wiring layer 83. The wiring layer 85 is formed on the lower surface of the insulating layer 84. The wiring layer 85 is electrically connected to the wiring layer 83 by via wiring extending through the insulating layer 84 in the thickness direction. The insulating layer 86 is formed on the lower surface of the insulating layer 84 and covers the wiring layer 85. The wiring layer 87 is formed on the lower surface of the insulating layer 86. The wiring layer 87 is electrically connected to the wiring layer 85 by via wiring extending through the insulating layer 86 in the thickness direction.

The solder resist layer 88 is formed on the lower surface of the insulating layer 86 and covers the wiring layer 87. The solder resist layer 88 includes openings 88X exposing parts of the lower surface of the wiring layer 87, which is the lowermost layer, as connection pads. The parts of the lower surface of the wiring layer 87 exposed from the openings 88X define external connection terminals 89. The external connection terminals 89 may be, for example, solder balls.

The wiring layer 91 is formed on the upper surface of the core substrate 71. The wiring layer 91 is electrically connected to the wiring layer 81 by the through-electrodes 73. Parts of the wiring layer 91 are electrically connected to the electronic components 76. The insulating layer 92 is formed on the upper surface of the core substrate 71 and covers the wiring layer 91. The wiring layer 93 is formed on the upper surface of the insulating layer 92. The wiring layer 93 is electrically connected to the wiring layer 91 by via wiring extending through the insulating layer 92 in the thickness direction. The insulating layer 94 is formed on the upper surface of the insulating layer 92 and covers the wiring layer 93. The wiring layer 95 is formed on the upper surface of the insulating layer 94. The wiring layer 95 is electrically connected to the wiring layer 93 by via wiring extending through the insulating layer 94 in the thickness direction. The insulating layer 96 is formed on the upper surface of the insulating layer 94 and covers the wiring layer 95. The wiring layer 97 is formed on the upper surface of the insulating layer 96. The wiring layer 97 is electrically connected to the wiring layer 95 by via wiring extending through the insulating layer 96 in the thickness direction.

The solder resist layer 98 is formed on the upper surface of the insulating layer 96 and covers the wiring layer 97. The solder resist layer 98 includes openings 98X exposing parts of the upper surface of the wiring layer 97, which is the uppermost layer, as connection pads. The openings 98X overlap the openings 38X in the solder resist layer 38 of the wiring substrate 10 in plan view.

### Structure of the Wiring Substrate 10

The wiring substrate 10 is mounted on the upper surface of the substrate 70. The wiring substrate 10 is mounted on the upper surface of the substrate 70 with the wiring layer 27 and the solder resist layer 38 facing the upper surface of the substrate 70. The wiring layer 27, which is exposed from the openings 38X in the solder resist layer 38, is bonded to the wiring layer 97, which is exposed from the openings 98X in the solder resist layer 98, by bonding members 99. The bonding members 99 bond the wiring layer 27 exposed from the openings 38X (i.e., surface-processed layer 61) to the wiring layer 97 exposed from the openings 98X. The bonding members 99 may be, for example, a solder layer. The material of the solder layer may be, for example, Pb-free solder of Sn—Ag, Sn—Cu, or Sn—Ag—Cu. The bonding members 99 may be, for example, a Cu—Ni—Sn electrolytic plating metal layer or a copper ink paste.

In this manner, the substrate 70 and the wiring substrate 10 are bonded by the bonding members 99 to form the semiconductor device 1 having a Package on Package (POP) configuration. The electronic components 76 incorporated in the substrate 70 may be electrically connected to the electronic components 50 incorporated in the wiring substrate 10 by the wiring layers 91, 93, 95, 97, 27, 26, 25, and the like.

### Structure of the Underfill Resin 100

The gap between the substrate 70 and the wiring substrate 10 is filled with the underfill resin 100. For example, the gap between the solder resist layer 98 and the solder resist layer 38 is filled with the underfill resin 100. The material of the underfill resin 100 may be, for example, an insulative resin such as an epoxy resin.

### Structure of the Semiconductor Chip 110

Each semiconductor chip 110 is flip-chip mounted on the wiring layer 20 of the wiring substrate 10. The semiconductor chips 110 are electrically connected by the external connection terminals 60 to the wiring layer 20 of the wiring substrate 10.

The semiconductor chips 110 may be, for example, a logic chip such as a central processing unit (CPU) chip or a graphics processing unit (GPU) chip.

Further, the semiconductor chips 110 may be, for example, a memory chip such as a dynamic random-access memory (DRAM) chip, a static random-access memory (SRAM) chip, or a flash memory chip.

When mounting the semiconductor chips 110 on the wiring substrate 10, a logic chip may be mounted in combination with a memory chip on the wiring substrate 10.

### Structure of the Underfill Resin 120

The gaps between the wiring substrate 10 and the semiconductor chip 110 are filled with the underfill resin 120. For example, the gaps between the semiconductor chips 110 are filled with the underfill resin 120. The material of the underfill resin 120 may be, for example, an insulative resin such as an epoxy resin.

In the present embodiment, the insulating layer 31 is an example of a first insulating layer, the wiring layer 22 is an example of a first wiring layer, the insulating layer 32 is an example of a second insulating layer, the insulating layers 32, 33, and 34 are an example of an N number of insulating layers, and the insulating layer 35 is an example of a filling insulating layer. The via wiring V4 is an example of first via wiring, the wiring layer 21B is an example of a second wiring layer, the projections 31A are each an example of a first projection, the via wiring V3 is an example of second via wiring, the wiring layer 21A is an example of a third wiring layer, the via wiring V2 is an example of third via wiring, and the wiring layer 20B is an example of a fourth wiring layer. The via wiring V5 is an example of fourth via wiring, the wiring layer 23 is an example of fifth via wiring, the via wiring V8 is an example of fifth via wiring, the wiring layer 25 is an example of a sixth wiring layer, the electronic components 50 are each an example of a first electronic component, and the electronic components 76 are each an example of a second electronic component.

### Method for Manufacturing the Wiring Substrate 10

A method for manufacturing the wiring substrate 10 will now be described. To simplify illustration, elements that will consequently become final elements of the wiring substrate 10 are given the same reference characters as the final elements.

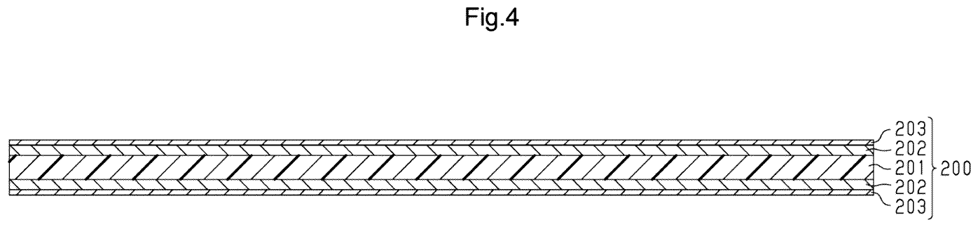

In the step illustrated in FIG. 4, a support 200 is prepared. The support 200 is constructed by, for example, sequentially stacking a metal foil 202 and a metal film 203 on both upper and lower surfaces of a base 201. The base 201 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. The metal foil 202 is, for example, a copper foil. The metal film 203 is, for example, a nickel (Ni) plating film. The material of the metal foil 202 is not limited to copper and may be a metal other than copper. Further, the material of the metal film 203 may be a material other than nickel as long as it is a conductive material that may be selectively etched and removed from the wiring layer 22 (refer to FIG. 2) in a subsequent step.

In the manufacturing method according to the present embodiment, a structure corresponding to part of the wiring substrate 10 is formed on both upper and lower surfaces of the support 200. For the sake of brevity, the description illustrates only the structure formed on the upper surface of the support 200.

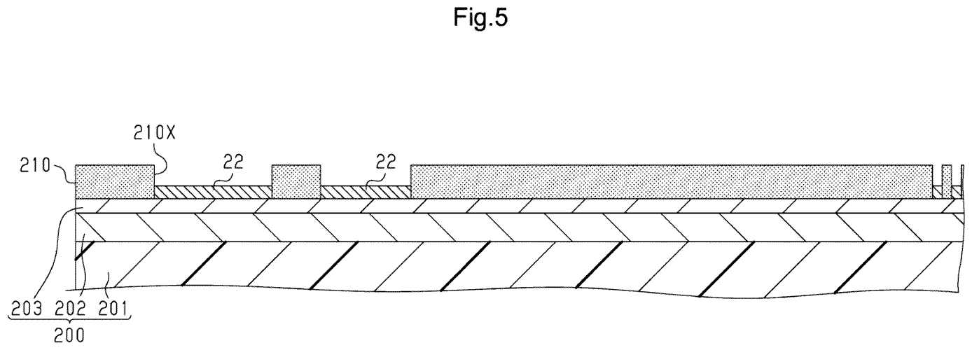

In the step illustrated in FIG. 5, a resist layer 210 including an opening pattern 210X is formed on the upper surface of the metal film 203 of the support 200. The opening pattern 210X exposes the upper surface of the metal film 203 at parts corresponding to regions where the wiring layer 22 is formed. The material of the resist layer 210 may be, for example, a material that resists plating in the plating process performed in the following step. The material of the resist layer 210 may be, for example, a photosensitive dry film resist or a liquid photoresist (e.g., dry film resist or liquid resist of novolac resin or acrylic resin). When using a photosensitive dry film, thermal compression bonding is performed to laminate a dry film onto the upper surface of the metal film 203, and a photolithography process is performed to pattern the dry film and form the resist layer 210 including the opening pattern 210X. When using a liquid photoresist, the resist layer 210 may be formed through a similar process.

Electrolytic plating is performed on the metal film 203 using the metal film 203 as a plating power feeding layer with the resist layer 210 acting as a plating mask. In this example, electrolytic plating, e.g., electrolytic Cu plating, is performed on the upper surface of the metal film 203 exposed from the opening pattern 210X of the resist layer 210. This step forms the wiring layer 22 on the upper surface of the metal film 203 exposed from the opening pattern 210X.

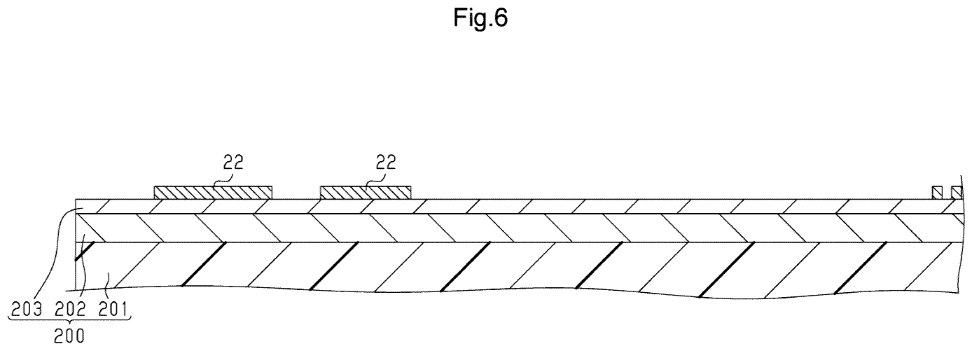

In the step illustrated in FIG. 6, the resist layer 210 of FIG. 5 is removed by an alkali delamination liquid (e.g., organic amine delamination liquid, caustic soda, acetone, or ethanol).

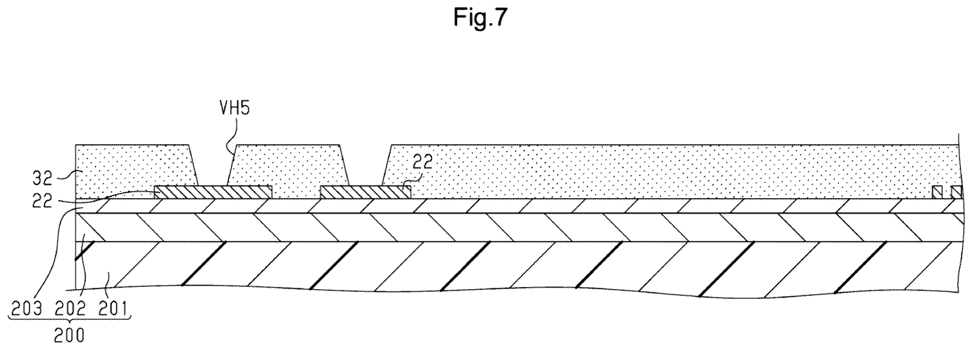

In the step illustrated in FIG. 7, the insulating layer 32, which covers the wiring layer 22, is formed on the upper surface of the metal film 203. When using a resin film as the insulating layer 32, for example, the resin film is laminated onto the upper surface of the metal film 203. While pressing the resin film, the resin film is heated to a temperature of, for example, approximately 130° C. to 200° C. that is higher than or equal to the curing temperature and then cured to form the insulation layer 32. The resin film may be, for example, a film of a thermosetting resin of which the main component is an epoxy resin. When a liquid or paste of an insulative resin is used as the insulating layer 32, the liquid or paste of insulative resin is applied to the upper surface of the metal film 203 through a spin coating process or the like. The applied insulative resin is heated to a temperature that is greater than or equal to the curing temperature to form the insulation layer 32. The liquid or paste of insulative resin may be, for example, a thermosetting resin of which the main component is an epoxy resin.

Then, through holes VH5 are formed in the insulating layer 32 at given locations to expose parts of the upper surface of the wiring layer 22. The through holes VH5 may be formed, for example, through laser processing using a CO₂ laser or a UV-YAG laser.

When forming the through holes VH5 through laser processing, a desmearing process is performed to remove smeared resin from the surface of the wiring layer 22 exposed at the bottom portions of the through holes VH5. The desmearing process of this step may be, for example, a wet desmearing process using a potassium permanganate solution.

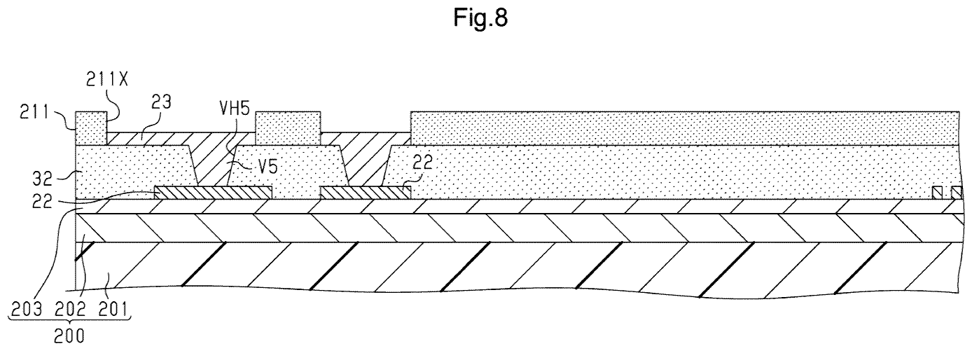

In the step illustrated in FIG. 8, a seed layer (not illustrated) is formed covering the entire upper surface of the insulating layer 32 and the entire wall surface of each through hole VH5. The seed layer is formed through, for example, a sputtering process or an electroless plating process. Then, a resist layer 211 including an opening pattern 211X at a given location is formed on the seed layer in a manner similar to the step illustrated in FIG. 5. The opening pattern 211X exposes the upper surface of the seed layer at parts corresponding to regions where the wiring layer 23 is formed. Electrolytic plating is performed on the seed layer using the seed layer as a plating power feeding layer with the resist layer 211 acting as a plating mask. This fills the through holes VH5 with the via wiring V5 and forms the wiring layer 23 in the opening pattern 211X.

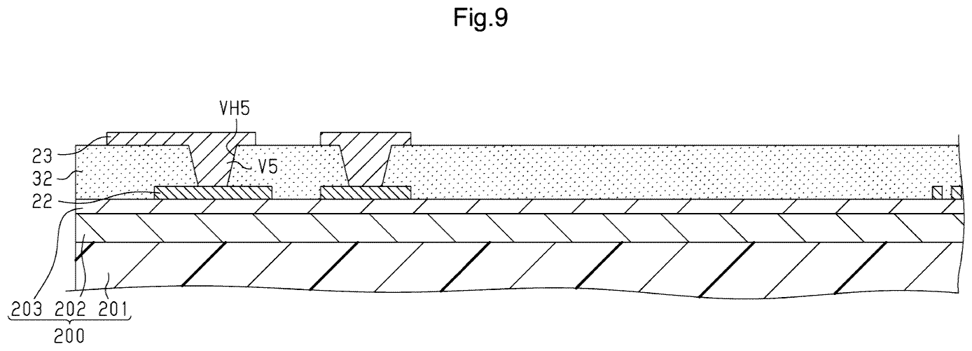

In the step illustrated in FIG. 9, the resist layer 211 of FIG. 8 is removed by an alkali delamination liquid (e.g., organic amine delamination liquid, caustic soda, acetone, or ethanol). Then, etching is performed to remove the unnecessary seed layer.

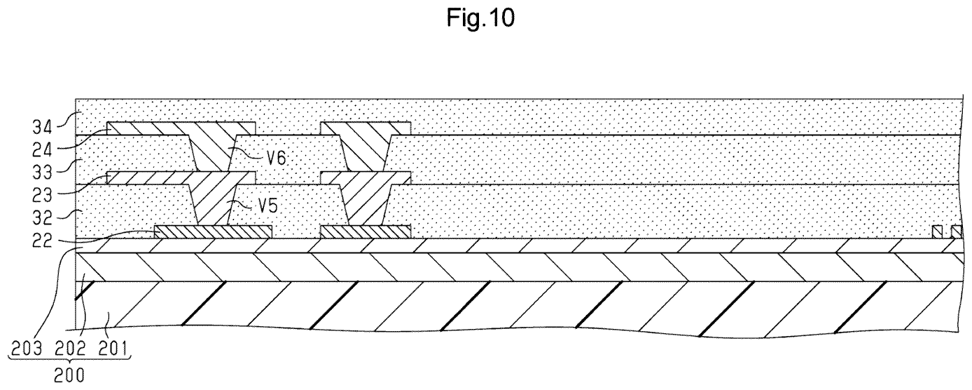

In the step illustrated in FIG. 10, the insulating layer 33 and the wiring layer 24 are formed on the upper surface of the insulating layer 32 in a manner similar to the steps of FIGS. 7 to 9. Further, the insulating layer 34 is formed on the upper surface of the insulating layer 33 covering the wiring layer 24. The insulating layer 34 is formed entirely on the upper and side surfaces of the wiring layer 24.

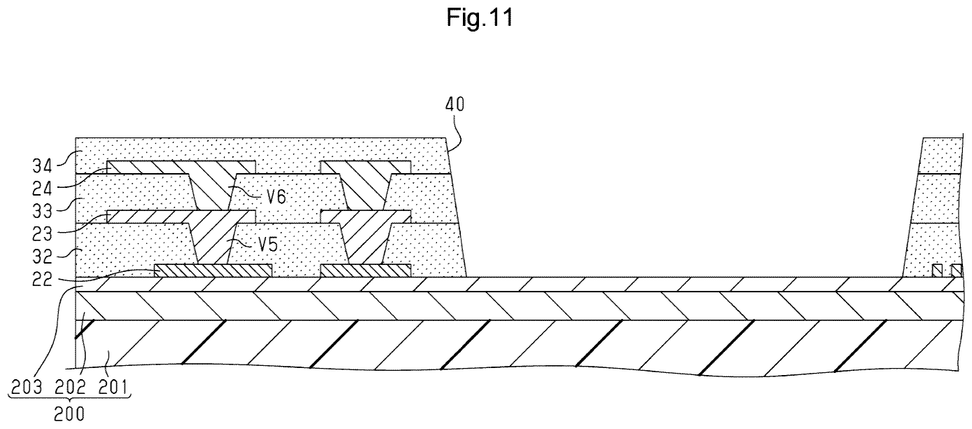

In the step illustrated in FIG. 11, the cavities 40, which are recessed from the upper surface of the insulating layer 34 toward the support 200, are formed to expose parts of the upper surface of the metal film 203. The cavities 40 extend through the insulating layers 34, 33, and 32 in the thickness direction. The cavities 40 may be formed, for example, through laser processing using a CO₂ laser or a UV-YAG laser.

When forming the cavities 40 through laser processing, a desmearing process is performed to remove smeared resin from the surface of the metal film 203 exposed at the bottom portions of the cavities 40.

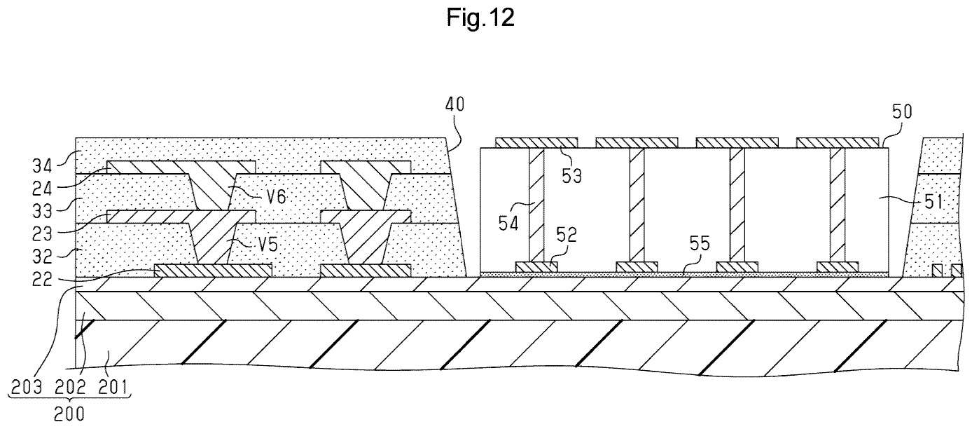

In the step illustrated in FIG. 12, the electronic components 50 are prepared with each including the main body 51, the first electrodes 52, the third electrodes 53, and the through-electrodes 54. Then, a mounter is used to fix the electronic components 50 to the upper surface of the metal film 203 exposed from the cavities 40 with an insulative resin 55, which is adhesive. The insulative resin 55 may be, for example, an adhesive agent in which a filler is mixed in a base resin, such as an epoxy resin. The insulative resin 55 may have a thickness of, for example, approximately 1 μm to 25 μm.

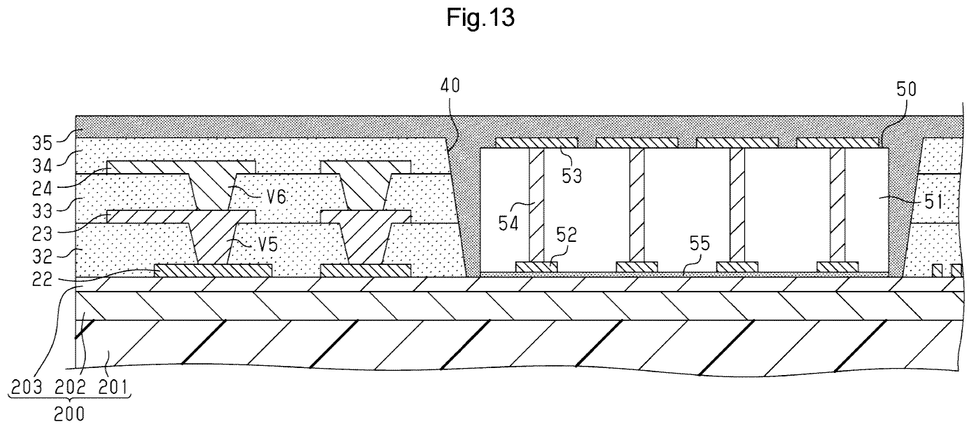

In the step illustrated in FIG. 13, the cavities 40 are filled with the insulating layer 35 that covers the upper surface of the insulating layer 34 in a manner similar to the step of FIG. 7. The insulating layer 35 covers the side surfaces of the insulative resin 55 and covers the entire surface of each electronic component 50 exposed from the insulative resin 55. The insulating layer 35 covers the entire upper surface of the metal film 203 exposed from the insulative resin 55.

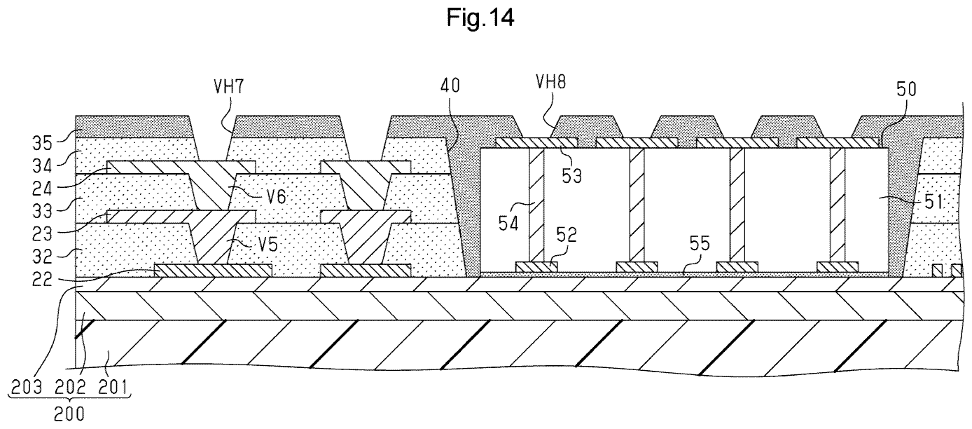

In the step illustrated in FIG. 14, through holes VH7, which extend through the insulating layers 34 and 35 in the thickness direction and expose parts of the upper surface of the wiring layer 24, are formed at given locations in the insulating layers 34 and 35. The through holes VH7 may be formed, for example, through laser processing using a CO₂ laser or a UV-YAG laser. Further, through holes VH8, each extending through the insulating layer 35 in the thickness direction and exposing part of the upper surface of one of the third electrodes 53, are formed at given locations in the insulating layer 35. The through holes VH8 may be formed, for example, through laser processing using a CO₂ laser or a UV-YAG laser. The through holes VH8 may be formed, for example, together with or separately from the through holes VH7.

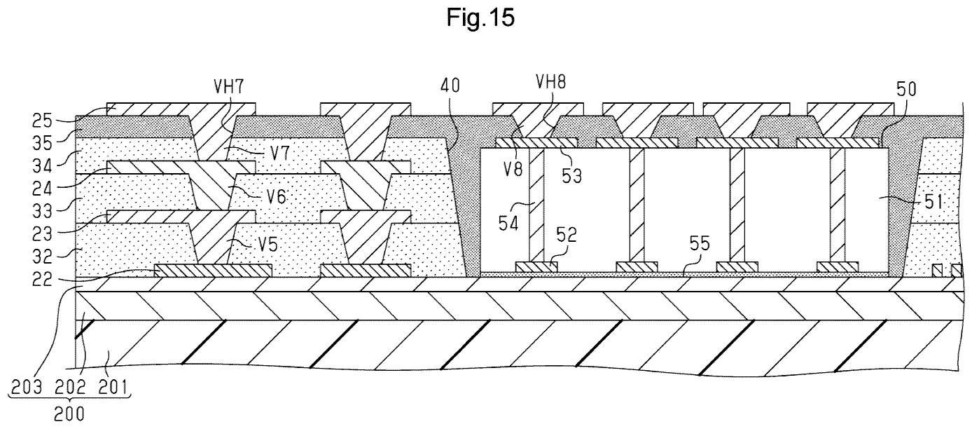

In the step illustrated in FIG. 15, each through hole VH7 is filled with the via wiring V7, and the wiring layer 25, which is electrically connected by the via wiring V7 to the wiring layer 24, is formed on the upper surface of the insulating layer 35 in a manner similar to the steps of FIGS. 8 and 9. Further, each through hole VH8 is filled with the via wiring V8, and the wiring layer 25, which is electrically connected by the via wiring V8 to the third electrodes 53, is formed on the upper surface of the insulating layer 35.

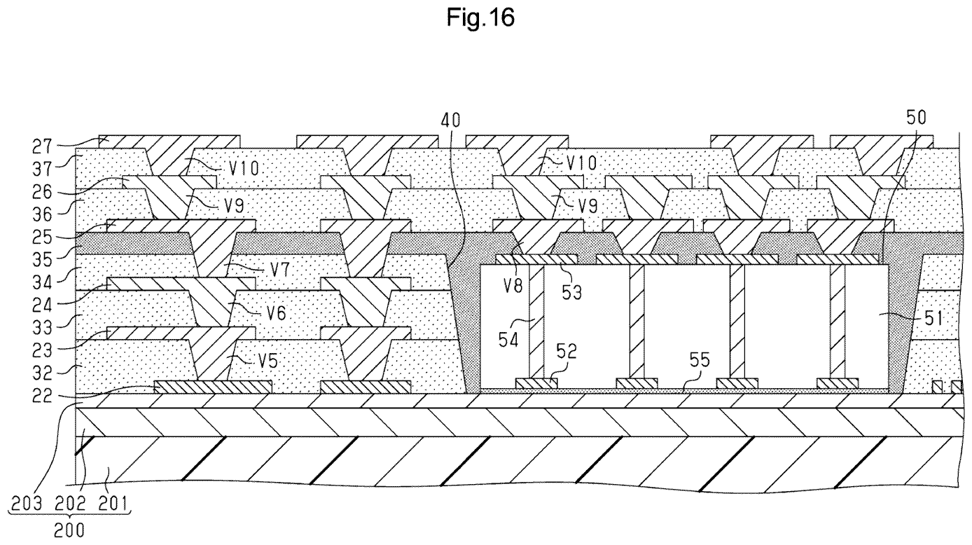

In the step illustrated in FIG. 16, the insulating layer 36, the wiring layer 26, the insulating layer 37, and the wiring layer 27 are sequentially stacked on the upper surface of the insulating layer 35 in a manner similar to the steps of FIGS. 7 to 9.

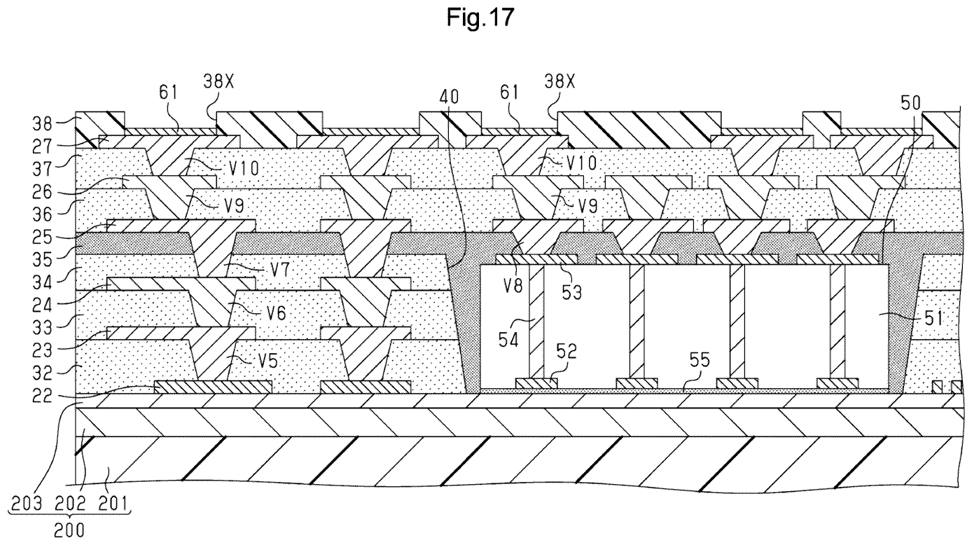

In the step illustrated in FIG. 17, the solder resist layer 38, which includes the openings 38X exposing parts of the upper surface of the wiring layer 27 as external connection pads, is formed on the upper surface of the insulating layer 37. The solder resist layer 38 may be formed by, for example, laminating a photosensitive solder resist film or applying a liquid of solder resist to the insulating layer 37 and patterning the resist into a given shape.

Then, the surface-processed layer 61 is formed on the upper surface of the wiring layer 27 exposed from the openings 38X. The surface-processed layer 61 is formed through, for example, an electroless plating process.

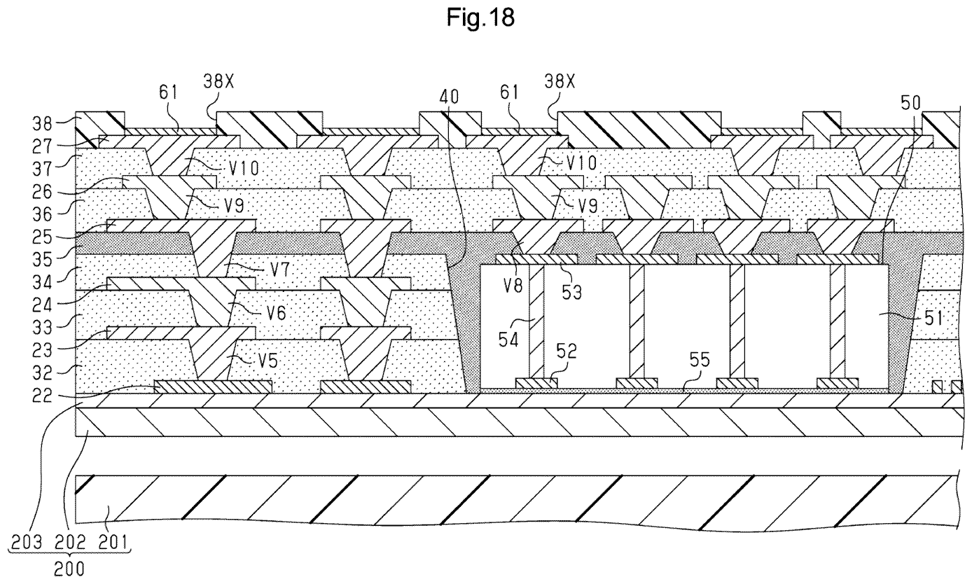

In the step illustrated in FIG. 18, the base 201 of the support 200 is removed from the metal foil 202. For example, the base 201 is mechanically removed from the metal foil 202.

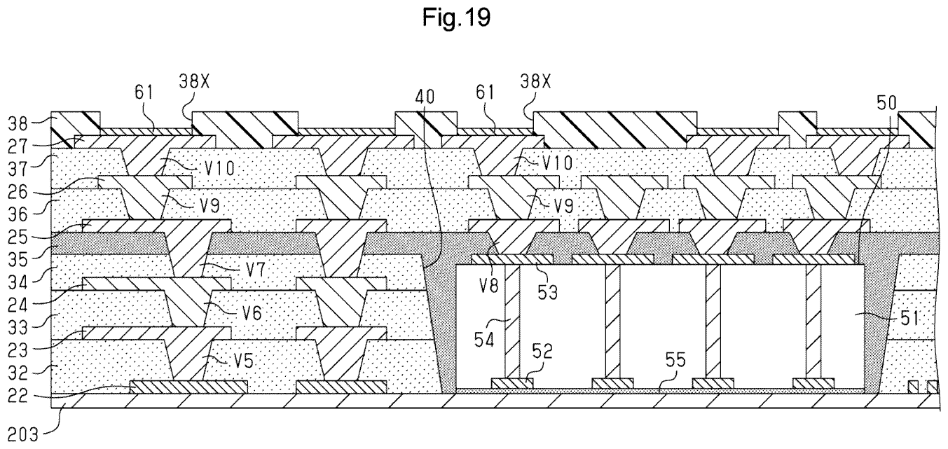

The metal foil 202 is then removed from the metal film 203. For example, the metal foil 202 is mechanically removed from the metal film 203. For example, the metal foil 202 is selectively etched and removed from the metal film 203. This exposes the lower surface of the metal film 203 to the outside as illustrated in FIG. 19.

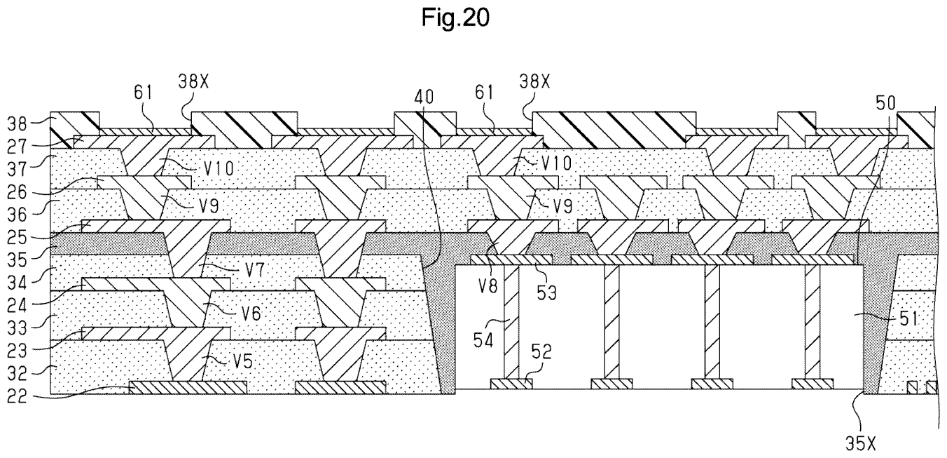

Then, the metal film 203 is removed from the wiring layer 22. For example, the metal film 203 is etched and removed. The metal film 203 is, for example, selectively etched and removed from the wiring layer 22. This exposes the lower surface of the wiring layer 22 and the lower surface of the insulating layer 32 to the outside as illustrated in FIG. 20. In this state, the lower surface of the wiring layer 22 and the lower surface of the insulating layer 32, which were in contact with the upper surface of the metal film 203 (refer to FIG. 19), are flat and shaped in conformance with the upper surface of the metal film 203. Thus, the lower surface of the wiring layer 22 is flush with the lower surface of the insulating layer 32.

Then, the insulative resin 55 illustrated in FIG. 19 is removed. This exposes the lower surface of each electronic component 50, that is, the lower surface of the main body 51 and the lower surface of each first electrode 52, to the outside. In this state, the recesses 35X are formed in the lower surface of the insulating layer 35.

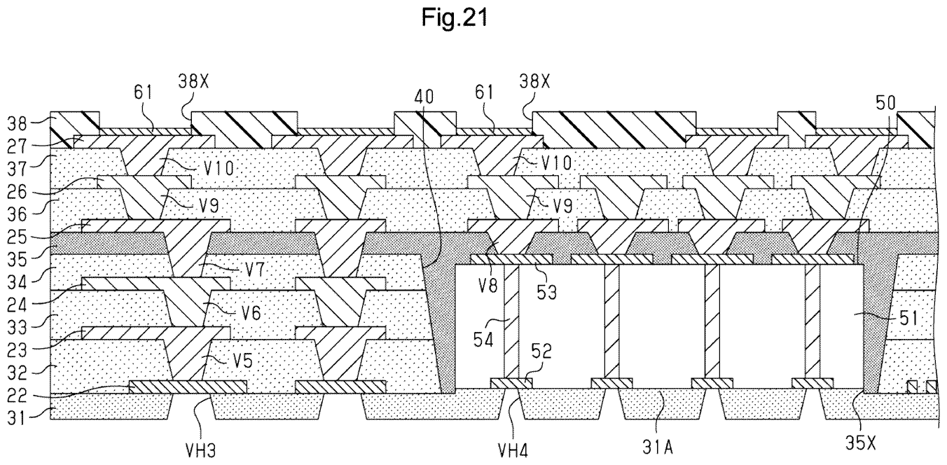

In the step illustrated in FIG. 21, the insulating layer 31, which covers the lower surface of the wiring layer 22, is formed on the lower surface of the insulating layer 32 in a manner similar to the step of FIG. 7. The recesses 35X are filled with the insulating layer 31. This forms the projections 31A of the insulating layer 31 in the recesses 35X.

Then, through holes VH3, which extend through the insulating layer 31 in the thickness direction and expose parts of the lower surface of the wiring layer 22, are formed at given locations in the insulating layer 31. The through holes VH3 may be formed, for example, through laser processing using a CO₂ laser or a UV-YAG laser. Further, through holes VH4, each extending through the insulating layer 31 in the thickness direction and exposing part of the lower surface of one of the first electrodes 52, are formed at given locations in the insulating layer 31. The through holes VH4 extend through the insulating layer 31 where the projections 31A are located. The through holes VH4 may be formed, for example, through laser processing using a UV laser or an excimer laser, which are suitable for microfabrication. The through holes VH4 may be formed, for example, together with or separately from the through holes VH4.

The through holes VH4 have a smaller diameter than the through holes VH3. The insulating layer 31 is formed on the lower surface of the insulating layer 32 and the lower surface of the wiring layer 22, which are flat. Thus, the insulating layer 31 has a flat lower surface. For example, the lower surface of the insulating layer 31 is flatter than the upper surface of the insulating layer 35, with which the cavities 40 are filled and which covers the upper surface of the insulating layer 34. The uniform thickness of the insulating layer 31 allows the small-diameter through holes VH4 to be formed in the insulating layer 31.

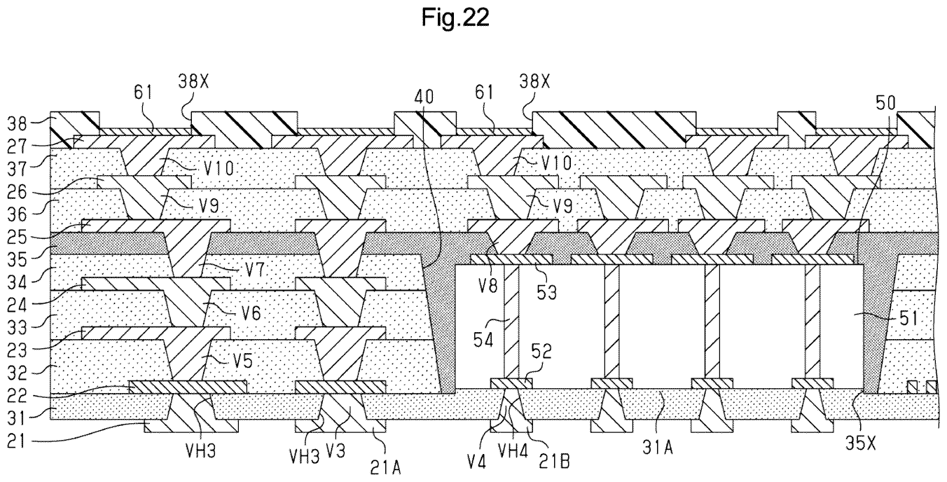

In the step illustrated in FIG. 22, in a manner similar to the steps of FIGS. 8 and 9, each through hole VH3 is filled with the via wiring V3. Further, the wiring layer 21A, which is electrically connected by the via wiring V3 to the wiring layer 22, is formed on the lower surface of the insulating layer 31. Each through hole VH4 is filled with the via wiring V4. Further, the wiring layer 21B, which is electrically connected by the via wiring V4, to the first electrodes 52, is formed on the lower surface of the insulating layer 31. This step forms the wiring layer 21, which includes the wiring layer 21A and the wiring layer 21B, on the lower surface of the insulating layer 31.

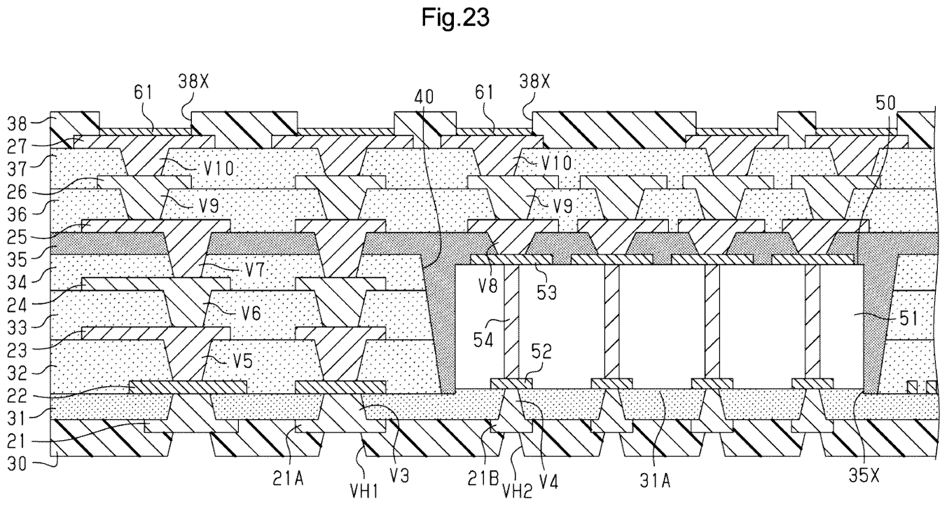

In the step illustrated in FIG. 23, the solder resist layer 30, which includes through holes VH1 and VH2 exposing parts of the lower surfaces of the wiring layers 21A and 21B, is formed in a manner similar to the step of FIG. 17.

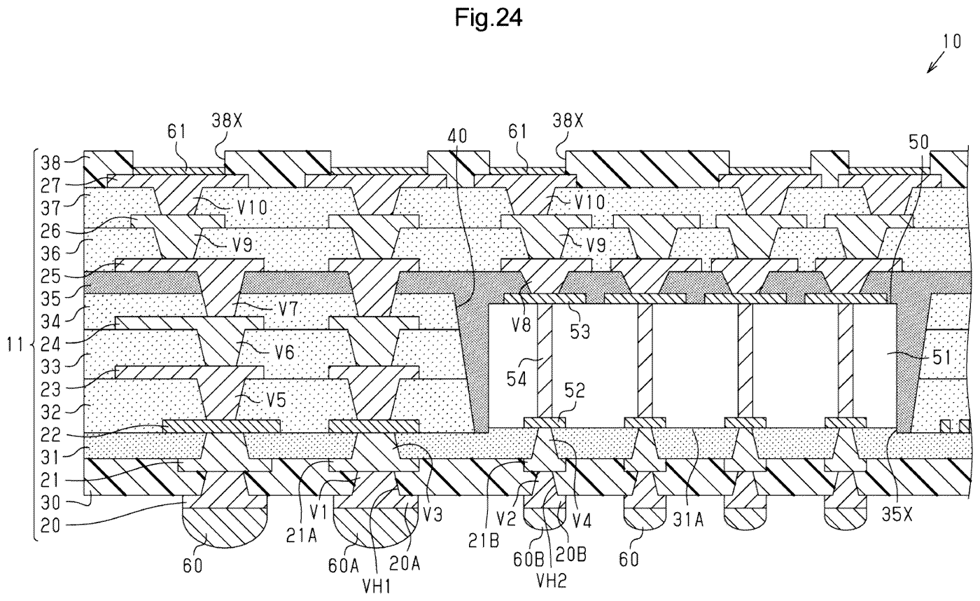

In the step illustrated in FIG. 24, each through hole VH1 is filled with the via wiring V1. Further, the solder resist layer 30, which is electrically connected by the via wiring V1 to the wiring layer 21A, is formed on the lower surface of the wiring layer 20A. Each through hole VH2 is filled with the via wiring V2. Further, the wiring layer 20B, which is electrically connected by the via wiring V2 to the wiring layer 21B, is formed on the lower surface of the solder resist layer 30. This step forms the wiring layer 20, which includes the wiring layer 20A and the wiring layer 20B, on the lower surface of the solder resist layer 30. Then, the external connection terminals 60 are formed on the lower surface of the wiring layer 20. In this example, the external connection terminals 60A are formed on the lower surface of the wiring layer 20A, and the external connection terminals 60B are formed on the lower surface of the wiring layer 20B.

The wiring substrate 10 in accordance with the present embodiment is manufactured through the steps described above.

### Method for Manufacturing the Semiconductor Device 1

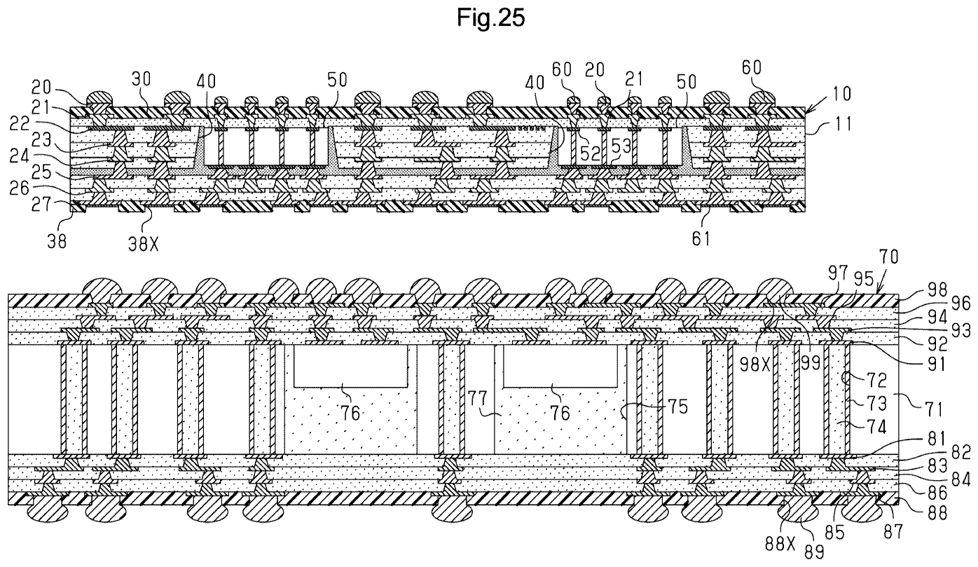

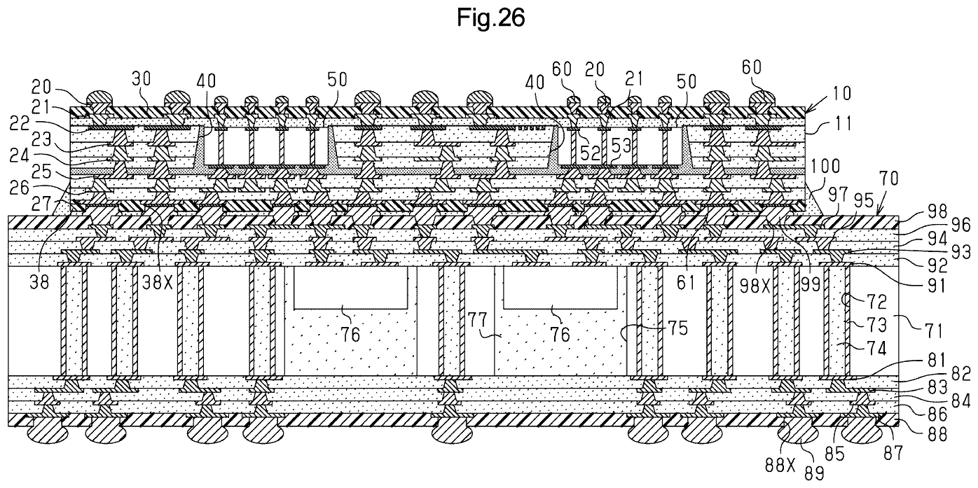

A method for manufacturing the semiconductor device 1 will now be described with reference to FIGS. 25 and 26. In FIGS. 25 and 26, the wiring substrate 10 is rotated by 180° from the state illustrated in FIG. 24.

In the step illustrated in FIG. 25, the substrate 70, which incorporates the electronic component 76, is manufactured. The substrate 70 may be manufactured through a known process. Thus, the process will not be described in detail. The bonding members 99 are formed on the wiring layer 97, which are exposed from the openings 98X in the solder resist layer 98 of the substrate 70.

Then, the wiring substrate 10 is arranged above the substrate 70. The wiring substrate 10 is arranged so that the solder resist layer 38 faces the solder resist layer 98 of the substrate 70. Further, the wiring substrate 10 is arranged so that the surface-processed layer 61 faces the bonding members 99.

In the step illustrated in FIG. 26, the wiring substrate 10 is mounted on the substrate 70. In this example, the surface-processed layer 61 of the wiring substrate 10 is bonded onto the bonding members 99 of the substrate 70. This electrically connects the wiring layer 27 of the wiring substrate 10 to the wiring layer 97 of the substrate 70 through the surface-processed layer 61 and the bonding members 99.

The gaps between the substrate 70 and the wiring substrate 10, which are bonded together, are filled with the underfill resin 100. Then, the underfill resin 100 is cured.

Subsequently, as illustrated in FIG. 3, semiconductor chips 110 are flip-chip mounted on the wiring layer 20 of the wiring substrate 10. This electrically connects the semiconductor chips 110 to the wiring layer 20 of the wiring substrate 10 through the external connection terminals 60. Further, the gaps between the semiconductor chips 110 and the wiring substrate 10 are filled with the underfill resin 120. The underfill resin 120 is then cured.

The semiconductor device 1 illustrated in FIG. 3 is manufactured through the steps described above.

### Advantages of the First Embodiment

The advantages of the first embodiment will now be described.

(1-1) The manufacturing method includes forming the wiring layer 22 on the support 200; and forming an N number (in the present embodiment, three) of the insulating layers 32, 33, and 34, including the insulating layer 32, on the support 200 so as to cover the wiring layer 22. The manufacturing method further includes forming the cavities 40, which expose parts of the upper surface of the support 200, in the N number of the insulating layers 32, 33, and 34; and fixing the electronic components 50 on the support 200 exposed from the cavities 40. The manufacturing method also includes filling the cavities 40 with the insulating layer 35 that covers the electronic components 50; removing the support 200; and forming the insulating layer 31 on a surface of the insulating layer 32 that was in contact with the support 200. Further, the manufacturing method includes forming the via wiring V4, extending through the insulating layer 31 in the thickness direction and electrically connected to the first electrodes 52 of the electronic components 50, and the wiring layer 21B, on the lower surface of the insulating layer 31, in which the wiring layer 21B is electrically connected by the via wiring V4 to the first electrodes 52.

In this structure, the electronic components 50 are not mounted on conductive pads exposed from cavities. Rather, the electronic components 50 are mounted on the support 200 exposed from the cavities 40. Thus, protective material for covering the conductive pads may be omitted. Further, the step for mounting the electronic components 50 in the cavities 40 may be simplified.

If the electronic components 50 were to be mounted on conductive pads exposed from cavities, for example, a solder layer for connecting the conductive pads and a thermosetting resin film such as a non-conductive film (NCF) would have to be arranged on the lower surface of each electronic component 50. Then, thermal compression bonding (TCB) would be performed to bond the electronic components 50 to the conductive pads.

In this case, heat and pressure bonds the solder layer, which is applied to the lower surfaces of the first electrode 52 on each electronic component 50, to the conductive pads. That is, in a state in which a given pressure acting toward the conductive pads is applied, the electronic components 50 are heated with a heater. This melts the solder layer and bonds the solder layer to the conductive pads. Thus, special equipment would be necessary to perform TCB and bond the electronic components 50 to the conductive pads. This increases manufacturing costs.

In this respect, the manufacturing method in accordance with the present embodiment does not mount the electronic components 50 on conductive pads. Rather, the electronic components 50 are mounted on the metal film 203 of the support 200. Thus, when disposing the electronic components 50 in the cavities 40, the first electrodes 52 of the electronic components 50 do not have to be electrically connected to the support 200. As a result, there is no need for a solder layer that bonds the conductive pads and the electronic components 50. Further, the solder layer does not have to be melted. That is, the electronic components 50 may be fixed onto the metal film 203 without performing TCB. Since special equipment for performing TCB is not necessary, the manufacturing cost may be lowered.

(1-2) The insulating layer 31 is formed on the lower surface of the insulating layer 32 that was in contact with the support 200. The via wiring V4 extends through the insulating layer 31 in the thickness direction and connects to the first electrodes 52 of the electronic components 50. The lower surface of the insulating layer 32, which was in contact with the support 200, is flat and shaped in conformance with the upper surface of the support 200. For example, compared with the upper surface of the insulating layer 35 with which the cavities 40 are filled, the lower surface of the insulating layer 31 is flatter. This allows the thickness of the insulating layer 31 to be uniform. Thus, the small-diameter through holes VH4 may be formed in the insulating layer 31 in a preferred manner, and the through holes VH4 may be filled with the small-diameter via wiring V4 in a preferred manner.

(1-3) The wiring substrate 10 includes the solder resist layer 30 and the via wiring V2. The solder resist layer 30 is formed on the lower surface of the insulating layer 31 and covers the wiring layer 21B. The via wiring V2 extends through the solder resist layer 30 in the thickness direction and is connected to the wiring layer 21B. The wiring substrate 10 includes the wiring layer 20B, which is formed on the lower surface of the solder resist layer 30 and electrically connected by the via wiring V2 to the wiring layer 21B. In this structure, the solder resist layer 30 is formed on the lower surface of the flat insulating layer 31. Thus, the solder resist layer 30 is formed with a flat lower surface in a preferred manner. This allows the thickness of the solder resist layer 30 to be uniform. Thus, the small-diameter through holes VH2 may be formed in the solder resist layer 30 in a preferred manner, and the through holes VH2 may be filled with the small-diameter via wiring V2 in a preferred manner. This allows the external connection terminals 60B to be arranged at a narrowed pitch on the lower surface of the wiring layer 20B, which is connected to the via wiring V2.

(1-4) The insulating layer 31 includes the projections 31A, which project from the upper surface of the insulating layer 31 into the cavities 40. The projections 31A are located in the cavities 40 and cover the first electrodes 52 of the electronic components 50. The insulating layer 31, which includes the projections 31A, is a single layer. This structure allows the via wiring V4 to be formed extending through the insulating layer 31, which is a single layer, in the thickness direction.

### Second Embodiment

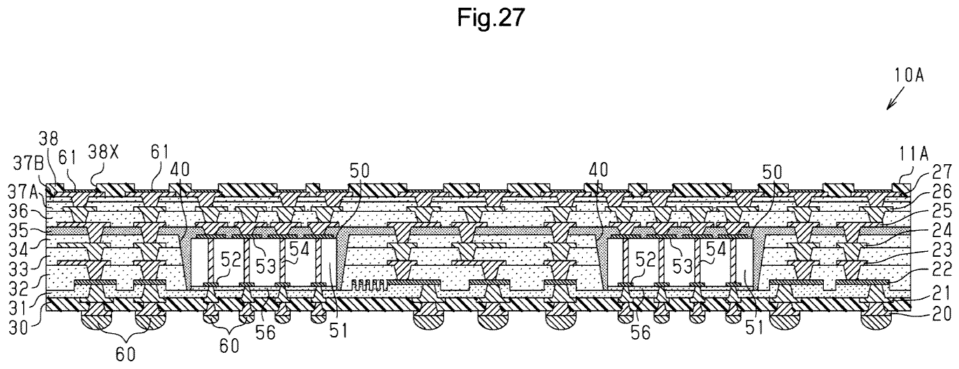

A second embodiment will now be described with reference to FIGS. 27 to 39. The description hereafter will focus on differences from the first embodiment. The same reference numerals are given to those components that are the same as the corresponding components illustrated in FIGS. 1 to 26. Such components will not be described in detail.

### Structure of the Wiring Substrate 10A

As illustrated in FIG. 27, a wiring substrate 10A includes a wiring structure 11A, one or more (two, in the present embodiment) cavities 40 formed in the wiring structure 11A, and one or more (two, in the present embodiment) electronic components 50 disposed in the cavities 40. The wiring substrate 10A incorporates the electronic components 50.

### Construction of the Wiring Structure 11A

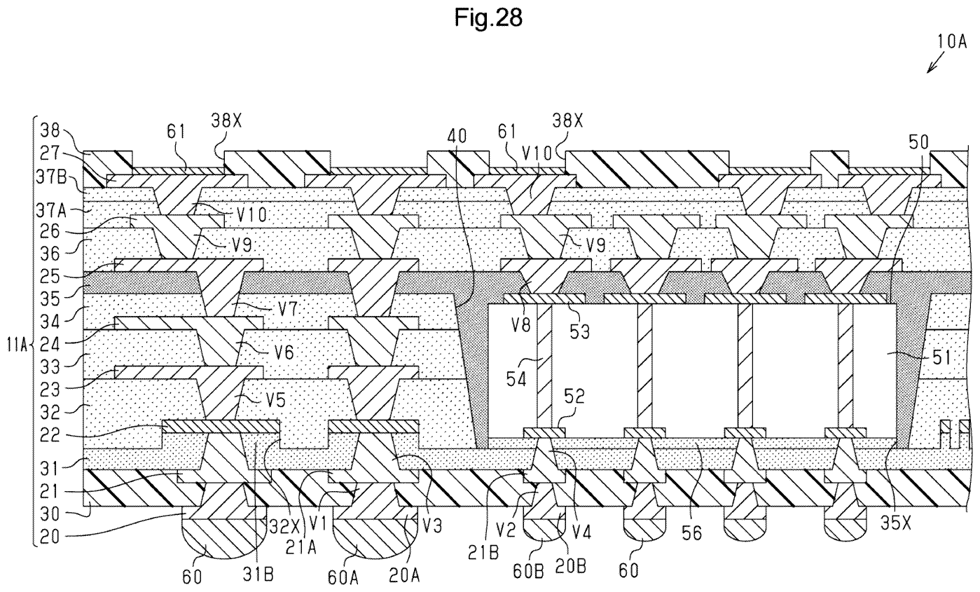

As illustrated in FIG. 28, the insulating layer 32 covers the upper surface and the side surfaces of the wiring layer 22. The insulating layer 32 includes recesses 32X that are recessed upward from the lower surface of the insulating layer 32. The recesses 32X overlap the wiring layer 22 in plan view. The recesses 32X expose the lower surface of the wiring layer 22.

The insulating layer 31 includes projections 31B projecting upward from the upper surface of the insulating layer 31. The recesses 32X are filled with the projections 31B. The projections 31B cover the lower surface of the wiring layer 22. In other words, the wiring layer 22 is formed on the projections 31B. Thus, the lower surface of the wiring layer 22 is located upward from the lower surface of the insulating layer 32. The insulating layer 32 covers the side surfaces of the projections 31B.

The insulating layer 31 of the present embodiment does not include the projection 31A (refer to FIG. 2) in each recess 35X. An insulative resin 56 is formed in each recess 35X of the present embodiment. The recess 35X is filled with the insulative resin 56. The insulative resin 56 is, for example, an insulating layer of which the main component is a non-photosensitive resin. The insulative resin 56 may be, for example, a material of which the main component is a thermosetting and non-photosensitive resin, such as an epoxy resin, an imide resin, a phenol resin, or a cyanate resin. Preferably, the material of the insulative resin 56 is of the same type of material forming the insulating layer 31. In the present embodiment, the insulating layer 31 and the insulative resin 56 form a double-layer structure acting as the first insulating layer.

The electronic components 50 are fixed to the upper surface of the insulating layer 31 exposed from the cavities 40 with the insulative resin 56. That is, the electronic components 50 are mounted on the insulative resin 56, which is arranged on the upper surface of the insulating layer 31.

The via wiring V3 extends through the insulating layer 31, which includes the projections 31B, in the thickness direction, and connect to the wiring layer 22. The via wiring V4 extends through the insulating layer 31 and the insulative resin 56 in the thickness direction and connect to the first electrodes 52. The via wiring V4 has a smaller diameter than the via wiring V3.

In the wiring structure 11A, an insulating layer 37A, which covers the wiring layer 26, and an insulating layer 37B are sequentially stacked on the upper surface of the insulating layer 36. The insulating layer 37A covers the upper surface and the side surfaces of the wiring layer 26. The insulating layer 37B covers the entire upper surface of the insulating layer 37A. The via wiring V10 extends through the insulating layer 37A and the insulating layer 37B in the thickness direction and connects to the wiring layer 26. The insulating layers 37A and 37B may be formed from, for example, a material of which the main component is a non-photosensitive resin. The insulating layers 37A and 37B may be formed from, for example, a material of which the main component is a thermosetting and non-photosensitive resin, such as an epoxy resin, an imide resin, a phenol resin, or a cyanate resin.

In the present example, the insulating layer 31 and the insulative resin 56 are an example of a first insulating layer, the insulating layer 31 is an example of a first insulative resin, the insulative resin 56 is an example of a second insulative resin, and the projections 31B are each an example of a second projection.

### Method for Manufacturing the Wiring Substrate 10A

A method for manufacturing the wiring substrate 10A will now be described. To simplify illustration, elements that will consequently become the final elements of the wiring substrate 10A are given the same reference characters as the final elements.

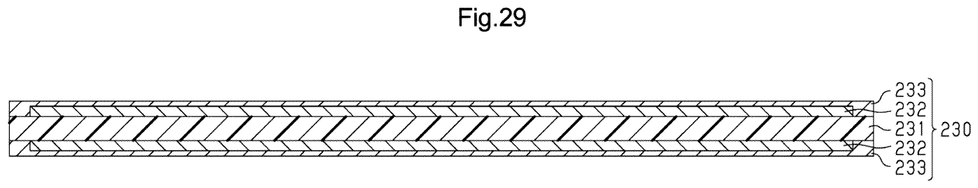

In the step illustrated in FIG. 29, a support 230 is prepared. The support 230 is constructed by, for example, sequentially stacking a metal film 232 and a metal film 233 on both upper and lower surfaces of a base 231. The base 231 is formed from, for example, a prepreg obtained by impregnating a reinforcement material such as a woven or non-woven cloth of glass fibers, aramid fibers, or liquid crystal polymer (LCP) fibers with a thermosetting insulative resin, such as an epoxy resin or a polyimide resin. Each metal film 232 is, for example, a Cu film. Each metal film 233 covers the side surfaces of the corresponding metal film 232. The metal film 233 covers the corresponding upper or lower surface of the base 231 exposed from the metal film 232. Each metal film 233 is, for example, a Cu plating film. The material of the metal film 232 is not limited to copper and may be a metal other than copper. The material of the metal film 233 is not limited to copper and may be a metal other than copper.

In the manufacturing method in accordance with the present embodiment, a structure corresponding to part of the wiring substrate 10A is formed on both upper and lower surfaces of the support 230. The description of the manufacturing method, however, will focus on only the structure formed on the upper surface of the support 230 for the sake of brevity.

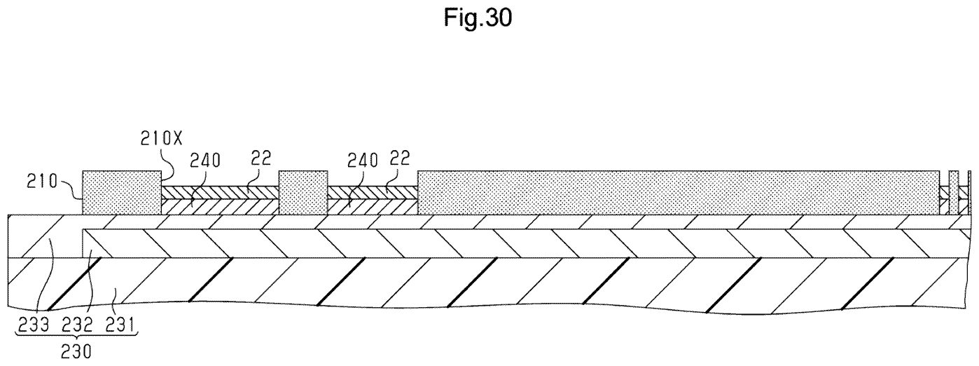

In the step illustrated in FIG. 30, the resist layer 210, which includes the opening pattern 210X, is formed on the upper surface of the metal film 233 of the support 230. The opening pattern 210X exposes the upper surface of the metal film 233 at parts corresponding to regions where the wiring layer 22 is formed.

Electrolytic plating is performed on the metal film 233 using the metal film 233 as a plating power feeding layer with the resist layer 210 acting as a plating mask. In this example, electrolytic plating, that is, electrolytic Ni plating, is performed on the upper surface of the metal film 233 exposed from the opening pattern 210X of the resist layer 210. This forms a metal layer 240 on the upper surface of the metal film 233 exposed from the opening pattern 210X. The material of the metal layer 240 may be a metal other than nickel as long as it is a conductive material that may be selectively etched and removed from the wiring layer 22 in a subsequent step. Then, electrolytic plating, that is, electrolytic Cu plating, is performed on the metal layer 240 using the metal film 233 as a plating power feeding layer. This forms the wiring layer 22 on the metal layer 240.

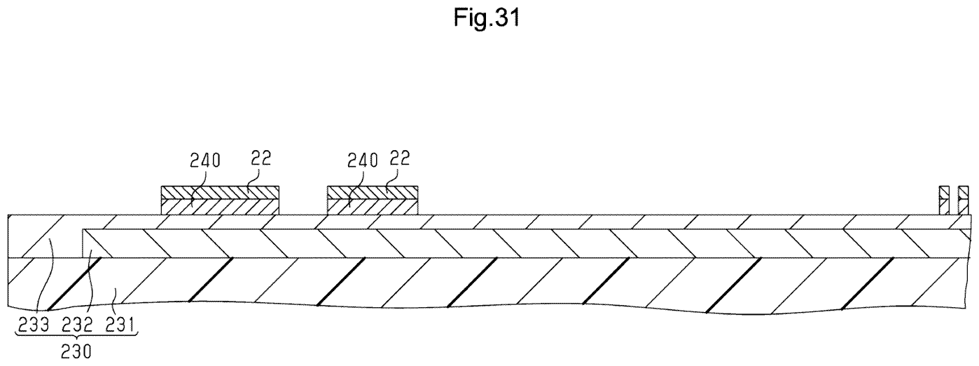

In the step illustrated in FIG. 31, the resist layer 210 of FIG. 30 is removed by an alkali delamination liquid (e.g., organic amine delamination liquid, caustic soda, acetone, or ethanol).

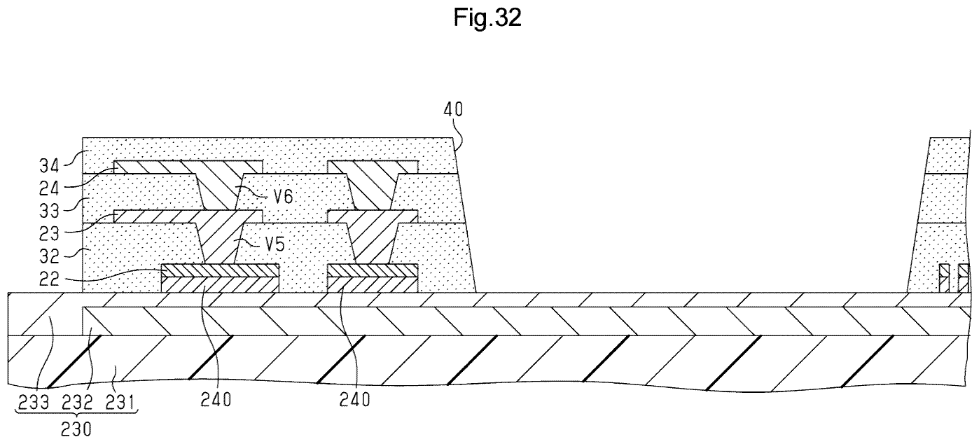

In the step illustrated in FIG. 32, the insulating layer 32, the wiring layer 23, the insulating layer 33, the wiring layer 24, and the insulating layer 34 are sequentially stacked on the upper surface of the metal film 233 in a manner similar to the steps of FIGS. 7 to 9. The insulating layer 32 entirely covers the side surfaces of the metal layer 240 and entirely covers the side surfaces of the wiring layer 22.

Then, the cavities 40, which are recessed from the upper surface of the insulating layer 34 toward the support 230, are formed to expose parts of the upper surface of the metal film 233 in a manner similar to the step of FIG. 11. The cavities 40 extend through the insulating layers 34, 33, and 32 in the thickness direction.

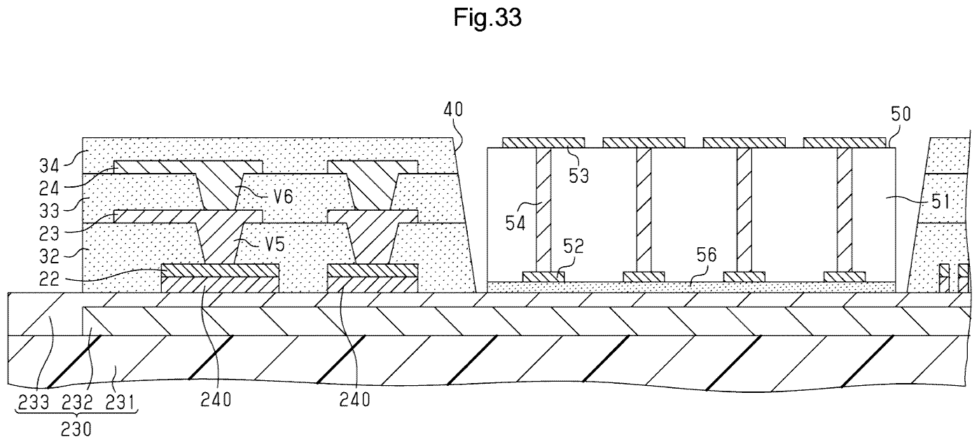

In the step illustrated in FIG. 33, a mounter is used to fix the electronic components 50 to the upper surface of the metal film 233 exposed from the cavities 40 with the insulative resin 56, which is adhesive, in a manner similar to the step of FIG. 12.

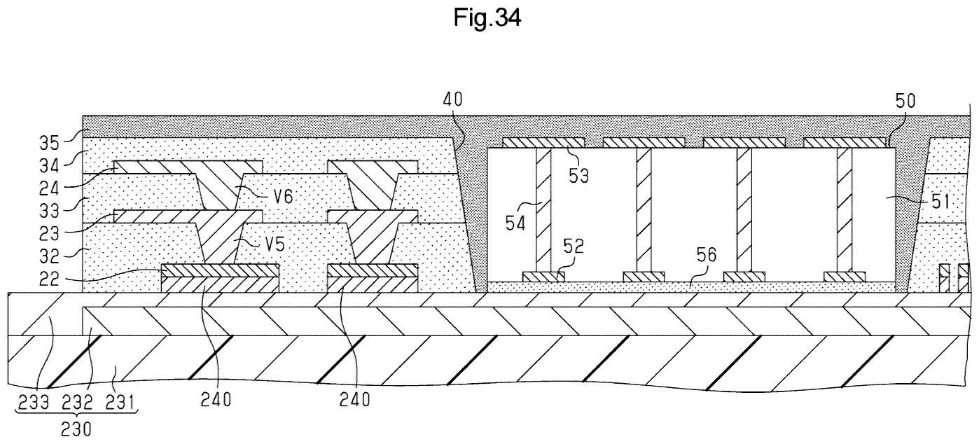

In the step illustrated in FIG. 34, the cavities 40 are filled with the insulating layer 35 that covers the upper surface of the insulating layer 34 in a manner similar to the step of FIG. 7.

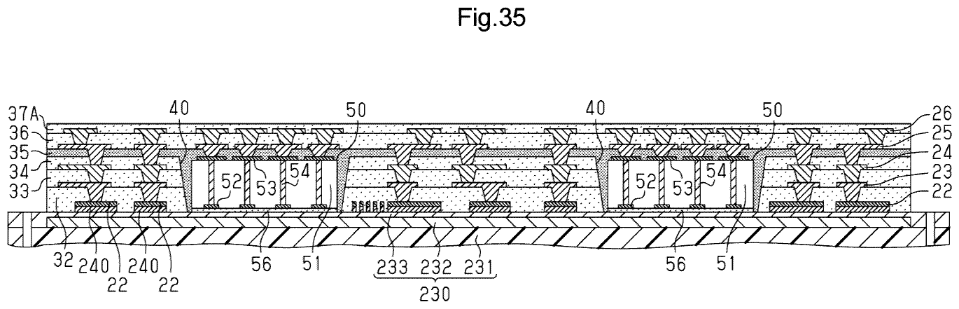

In the step illustrated in FIG. 35, the wiring layer 25, the insulating layer 36, the wiring layer 26, and the insulating layer 37A are sequentially stacked on the upper surface of the insulating layer 35 in a manner similar to the steps of FIGS. 7 to 9. The insulating layer 37A is formed entirely on the upper and side surfaces of the wiring layer 26.

Then, a slicer or the like is used to cut away the peripheral region of the support 230. The peripheral region of the support 230 is the part extending outward from the outer surfaces of the insulating layers 32, 33, 34, 35, 36, and 37A.

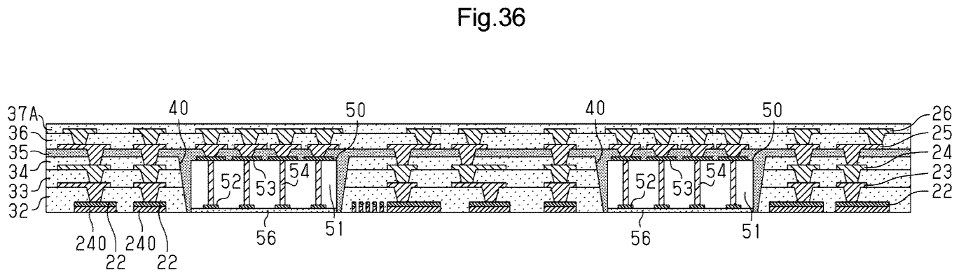

In the step illustrated in FIG. 36, the support 230, which was cut in the step of FIG. 35, is removed in a manner similar to the steps of FIGS. 18 to 20. The metal film 233 (refer to FIG. 35), which is a Cu plating film, is selectively etched and removed from the metal layer 240, which is a Ni layer. The surface of the wiring layer 26 is covered by the insulating layer 37A. This restricts removal of the wiring layer 26 during the etching.

This step exposes the lower surface of the insulating layer 32, the lower surface of the metal layer 240, and the lower surface of the insulative resin 56 to the outside. In this state, the lower surface of the insulating layer 32, the lower surface of the metal layer 240, and the lower surface of the insulative resin 56, which were in contact with the metal film 233 (refer to FIG. 35), are flat and shaped in conformance with the upper surface of the metal film 233. Thus, the lower surface of the insulating layer 32 is flush with the lower surface of the metal layer 240 and the lower surface of the insulative resin 56.

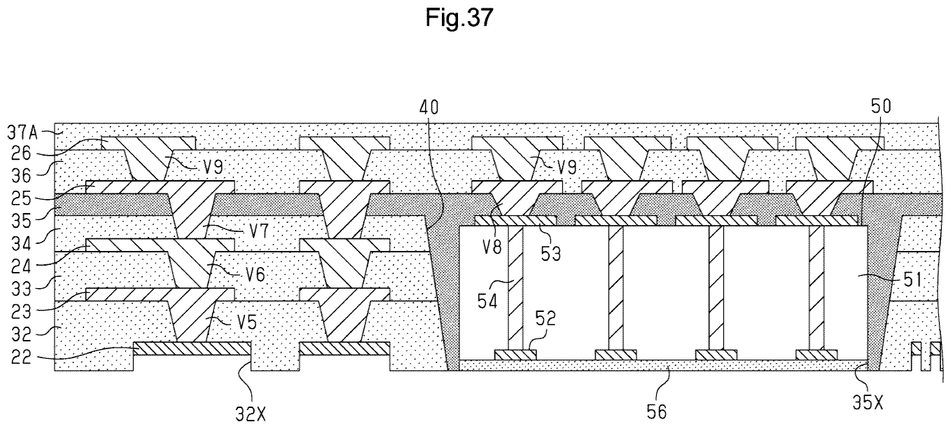

The metal film 240 is then removed. The metal film 240 is, for example, selectively etched and removed from the wiring layer 22. This exposes the lower surface of the wiring layer 22 to the outside, as illustrated in FIG. 37. In this state, the recesses 32X are formed in the lower surface of the insulating layer 32.

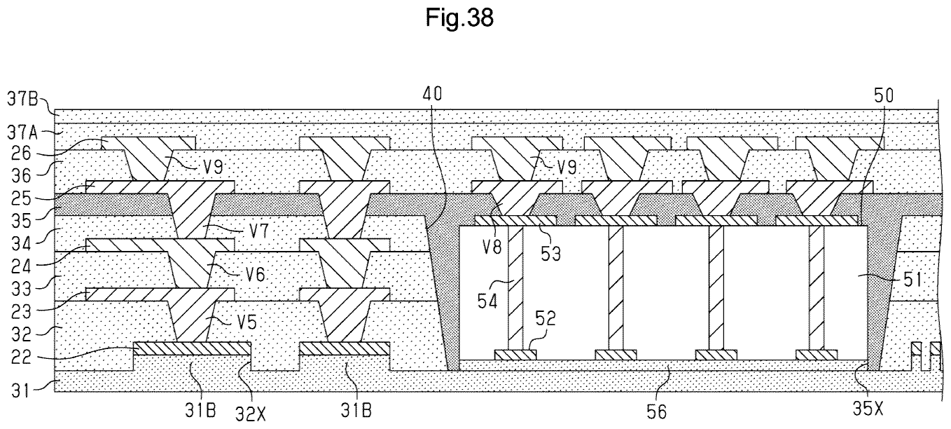

In the step illustrated in FIG. 38, the insulating layer 31, which covers the lower surface of the wiring layer 22 and the lower surface of the insulative resin 56, is formed on the lower surface of the insulating layer 32 in a manner similar to the step of FIG. 7. The recesses 32X are filled with the insulating layer 31. This forms the projections 31B of the insulating layer 31 in the recesses 32X. Further, the insulating layer 37B, which covers the entire upper surface of the insulating layer 37A, is formed on the upper surface of the insulating layer 37A.

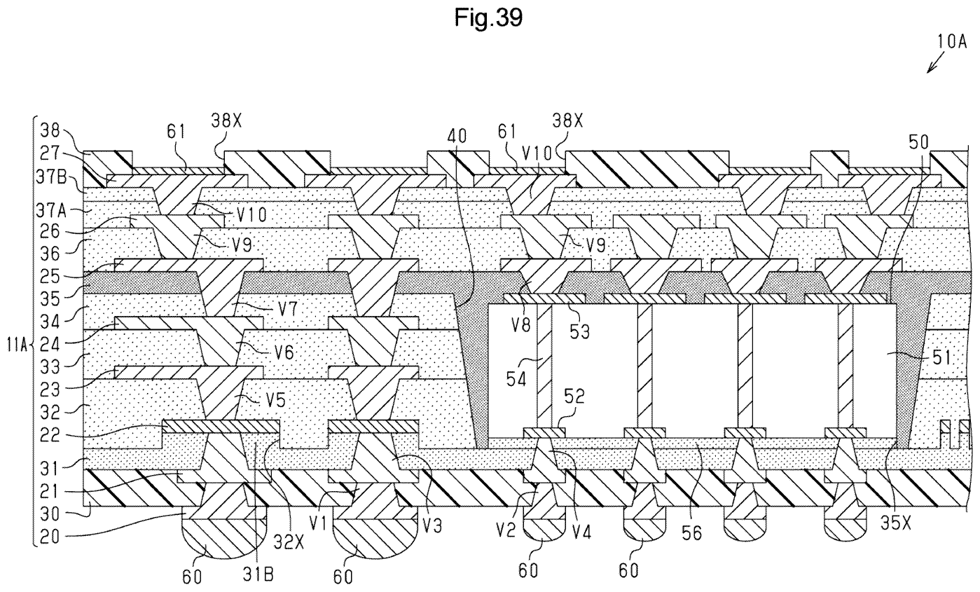

In the step illustrated in FIG. 39, the wiring layer 21 is formed on the lower surface of the insulating layer 31, and the wiring layer 27 is formed on the upper surface of the insulating layer 37B, in a manner similar to the steps of FIGS. 8 and 9. Then, a step similar to the step of FIG. 17 is performed to form the solder resist layer 30 on the lower surface of the insulating layer 31 and form the solder resist layer 38 on the upper surface of the insulating layer 37B. Then, the wiring layer 20 is formed on the lower surface of the solder resist layer 30. Further, the external connection terminals 60 are formed on the lower surface of the wiring layer 20.

The wiring substrate 10A in accordance with the present embodiment is manufactured through the steps described above.

### Advantages of Second Embodiment

In addition to advantages (1-1) to (1-3) of the first embodiment, the second embodiment has the advantages described below.

(2-1) The lower surface of the insulating layer 32 includes the recesses 32X, and the recesses 32X are filled with the projections 31B of the insulating layer 31. The insulating layer 32 covers the side surfaces of the projections 31B. This increases the area of contact between the insulating layer 31 and the insulating layer 32, and improves the adhesion between the insulating layer 31 and the insulating layer 32.

(2-2) The insulative resin 56 is not removed after being used to fix the electronic components 50 onto the support 230 exposed from the cavities 40. Thus, the insulating layer 31 is formed on the lower surface of the insulative resin 56. This allows the step of removing the insulative resin 56 to be omitted.

### Third Embodiment

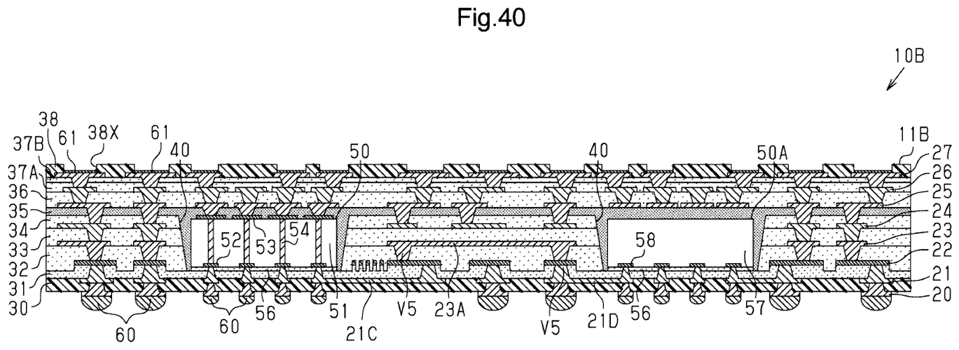

A third embodiment will now be described with reference to FIGS. 40 to 45. The description hereafter will focus on differences from the second embodiment. The same reference numerals are given to those components that are the same as the corresponding components illustrated in FIGS. 1 to 39. Such components will not be described in detail.

As illustrated in FIG. 40, a wiring substrate 10B includes a wiring structure 11B, one or more (two, in the present embodiment) cavities 40 formed in the wiring structure 10B, an electronic component 50 disposed in one cavity 40, and an electronic component 50A disposed in the other cavity 40. The wiring substrate 10 incorporates the electronic components 50 and 50A.

### Structure of the Electronic Component 50A

The electronic component 50A includes a main body 57 and the first electrodes 58 arranged in the lower portion of the electronic component 50A. The electronic component 50A of the present embodiment includes multiple first electrodes 58.

The electronic component 50A may be, for example, a semiconductor element, a quartz oscillator, a chip component, or a silicon bridge that has no through-electrodes. Examples of a chip component include a chip capacitor, a chip resistor, and a chip inductor. Further, the electronic component 50 may be a wiring structural body formed by an organic resin.

The main body 57 is, for example, box-shaped. The main body 57 may have a thickness of, for example, approximately 50 μm to 100 μm. The main body 57 is formed from, for example, silicon (Si) or silicon carbide (SIC).

The material of the first electrodes 58 may be, for example, a metal such as aluminum (Al) or copper (Cu) or an alloy including at least one of these metals.

Each first electrode 58 is, for example, embedded in the main body 57. The lower surface of the first electrode 58 is exposed from the lower surface of the main body 57. Further, the lower surface of the first electrode 58 is, for example, flush with the lower surface of the main body 57. The first electrode 58 may have a thickness of, for example, approximately 2 μm to 20 μm. The first electrode 58 may project downward from the lower surface of the main body 57.

The electronic component 50A has no electrodes in the upper portion of the electronic component 50A. Further, the electronic component 50A has no through-electrodes extending through the main body 57 in the thickness direction.

The wiring layer 21 of the present embodiment includes wiring patterns 21C and 21D laid out in the lower surface of the insulating layer 31 in the planar direction. The wiring pattern 21C, for example, electrically connects parts of the wiring layer 21 that are connected to the wiring layer 22 to parts of the wiring layer 21 that are connected to the first electrodes 52 of the electronic component 50. The wiring pattern 21D, for example, electrically connects the parts of the wiring layer 21 that are connected to the wiring layer 22 to parts of the wiring layer 21 that are connected to the first electrodes 58 of the electronic component 50A.

The electronic component 50A is fixed by the insulative resin 56 to the upper surface of the insulating layer 31 exposed from the corresponding cavity 40. That is, the electronic component 50A is mounted on the insulative resin 56, which is arranged on the upper surface of the insulating layer 31.

The wiring layer 23 of the present embodiment includes a wiring pattern 23A laid out in the upper surface of the insulating layer 32 in the planar direction. The wiring pattern 23A, for example, is connected by the via wiring V5 to the parts of the wiring layer 22 electrically connected to the wiring pattern 21C, and is connected by the via wiring V5 to the parts of the wiring layer 22 electrically connected to the wiring pattern 21D.

The electronic component 50 and the electronic component 50A are, for example, electrically connected to each other by the wiring layers 21, 22, 23, and the like. In this example, the electronic component 50 and the electronic component 50A are electrically connected to each other by the wiring patterns 21C and 21D, the wiring layer 22, the wiring pattern 23A, and the like.

### Method for Manufacturing the Wiring Substrate 10B

A method for manufacturing the wiring substrate 10B will now be described. To simplify illustration, elements that will consequently become the final elements of the wiring substrate 10B are given the same reference characters as the final elements.

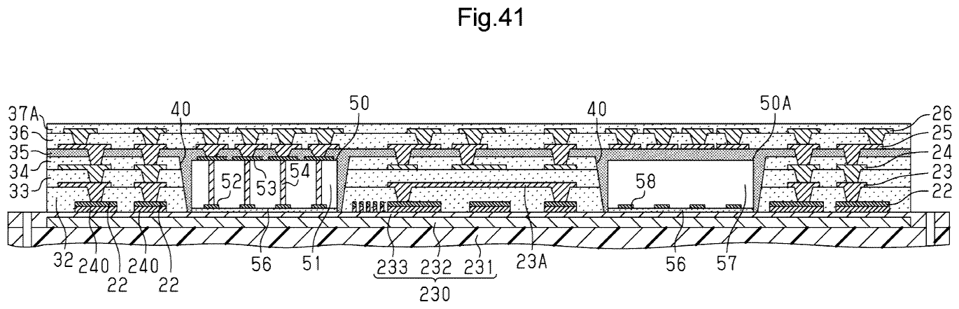

First, steps similar to the steps of FIGS. 29 to 35 are performed to manufacture the structure illustrated in FIG. 41. In this state, the wiring layer 23 is formed including the wiring pattern 23A. The electronic component 50A is fixed to the upper surface of the metal film 233, which is exposed from one of the cavities 40, with the insulative resin 56 in the same manner as the electronic component 50. The electronic component 50A is fixed in a state in which the first electrodes 58 face the insulative resin 56.

Then, a step similar to the step of FIG. 35 is performed to cut away the peripheral region of the support 230.

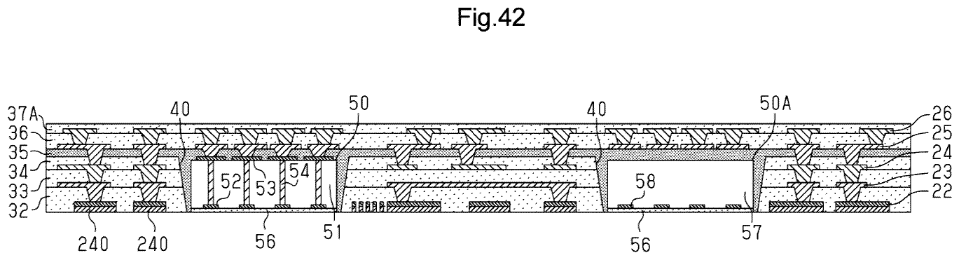

In the step illustrated in FIG. 42, the support 230, which was cut in the step of FIG. 41, is removed in a manner similar to the step of FIG. 36. This exposes the lower surface of the insulating layer 32, the lower surface of the metal layer 240, and the lower surface of the insulative resin 56 to the outside.

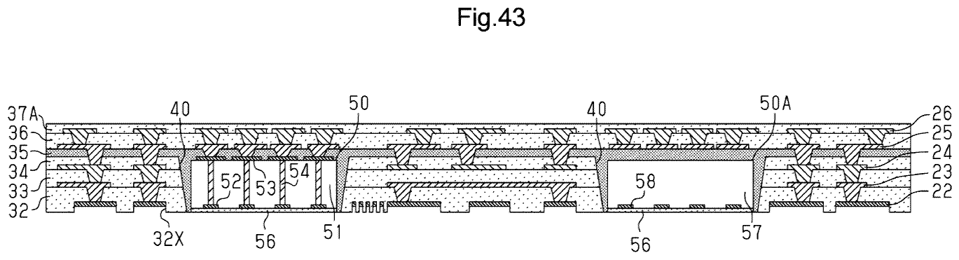

The metal film 240 is then removed. The metal film 240 is, for example, selectively etched and removed from the wiring layer 22. This exposes the lower surface of the wiring layer 22 to the outside, as illustrated in FIG. 43. In this state, the recesses 32X are formed in the lower surface of the insulating layer 32.

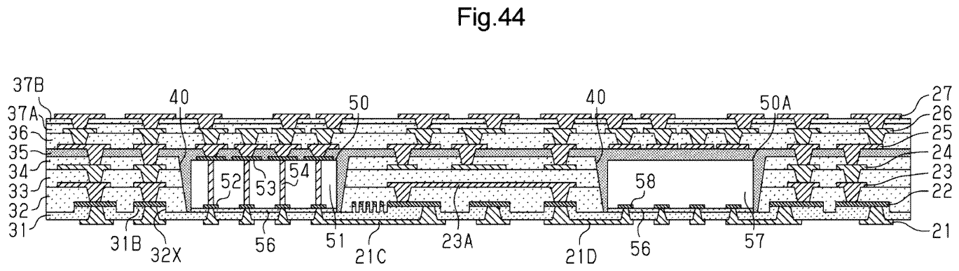

In the step illustrated in FIG. 44, the insulating layer 31, which covers the lower surface of the wiring layer 22 and the lower surface of the insulative resin 56, is formed on the lower surface of the insulating layer 32 in a manner similar to the step of FIG. 38. The recesses 32X are filled with the insulating layer 31. Further, the insulating layer 37B, which covers the entire upper surface of the insulating layer 37A, is formed on the upper surface of the insulating layer 37A.

Then, steps similar to the steps of FIGS. 8 and 9 are performed to form the wiring layer 21 on the lower surface of the insulating layer 31, and form the wiring layer 27 on the upper surface of the insulating layer 37B. In this state, the wiring layer 21, which includes the wiring patterns 21C and 21D is formed. This electrically connects the electronic component 50 and the electronic component 50A to each other through the wiring patterns 21C and 21D, the wiring layer 22, the wiring pattern 23A, and the like.

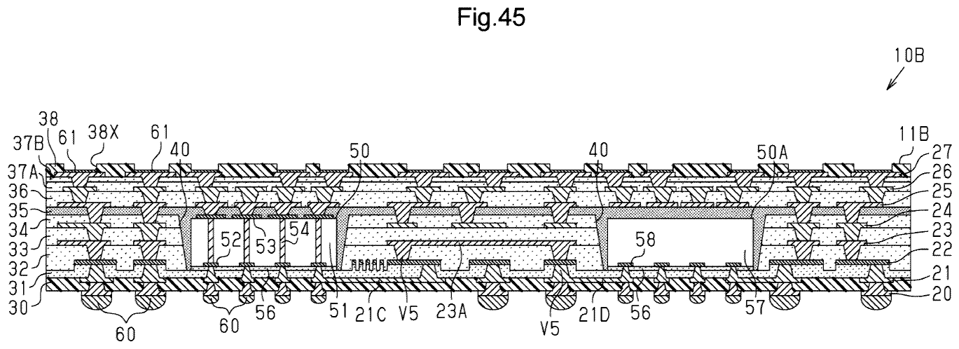

In the step illustrated in FIG. 45, the solder resist layer 30 is formed on the lower surface of the insulating layer 31, and the solder resist layer 38 is formed on the upper surface of the insulating layer 37B, in a manner similar to the step of FIG. 17. The wiring layer 20 is then formed on the lower surface of the solder resist layer 30. Further, the external connection terminals 60 are formed on the lower surface of the wiring layer 20.

The wiring substrate 10B in accordance with the present embodiment is manufactured through the steps described above.

### Advantages of Third Embodiment

The third embodiment has advantages (1-1) to (1-3) of the first embodiment and advantages (2-1) and (2-2) of the second embodiment.

### Modified Examples

The above embodiments may be modified as described below. The above-described embodiments and the modified examples described below may be combined as long as there is no technical contradiction.

The structures of the wiring substrates 10, 10A, and 10B in accordance with the above embodiments may be modified.

In the wiring substrates 10, 10A, and 10B in accordance with the above embodiments, there is no limitation to the number of wiring layers and the number of insulating layers stacked on the lower surface of the insulating layer 32. For example, only the insulating layer 31 and only the wiring layer 21 may be stacked on the lower surface of the insulating layer 32. That is, the solder resist layer 30 and the wiring layer 20 may be omitted. In this case, for example, the external connection terminals 60 are arranged on the lower surface of the wiring layer 21.

The insulating layer 31 in each of the above embodiments may include both the projections 31A and the projections 31B.

The projections 31A and the projections 31B may both be omitted from the insulating layer 31 in each of the above embodiments.

In the wiring substrates 10, 10A, and 10B in accordance with the above embodiments, there is no particular limitation to the number of wiring layers and insulating layers stacked on the upper surface of the cavity-filling insulating layer 35.

The solder resist layer 38 may be omitted in the above embodiments.

The wiring structures 11, 11A, and 11B of the above embodiments each include three cavity-forming insulating layers, namely, the insulating layers 32, 33, and 34. Instead, the cavities may be formed by one insulating layer, two insulating layers, or four or more insulating layers.

The wiring substrates 10, 10A, and 10B in accordance with the above embodiments may be modified to incorporate only the electronic component 50A.

There is no limitation to the number of the electronic components 50 and 50A incorporated in the wiring substrates 10, 10A, and 10B of the above embodiments. For example, the wiring substrates 10, 10A, and 10B may each incorporate only one electronic component 50. For example, the wiring substrates 10, 10A, and 10B may each incorporate three or more electronic components 50.

In the wiring substrates 10, 10A, and 10B in accordance with the above embodiments, each cavity 40 accommodates only one of the electronic components 50 and 50A. This, however, is not a limitation. For example, more than one of the electronic components 50 and 50A may be disposed in each cavity 40.

In the above embodiments, the wiring substrates 10, 10A, and 10B incorporate the electronic components 50 including the through-electrodes 54. For example, the wiring substrates 10, 10A, and 10B may incorporate electronic components that do not include the through-electrodes 54.

In the above embodiments, the wiring substrates 10, 10A, and 10B incorporate the electronic components 50 that include electrodes of two types, namely, the first electrodes 52 and the third electrodes 53. This, however, is not a limitation. For example, the wiring substrates 10, 10A, and 10B may incorporate electronic components including electrodes of three or more types.

The structure of the substrate 70 in the above embodiments may be modified.

In the substrate 70 of the above embodiments, there is no particular limitation to the number of wiring layers and insulating layers stacked on the upper surface of the core substrate 71.

In the substrate 70 of the above embodiments, there is no particular limitation to the number of wiring layers and insulating layers stacked on the lower surface of the core substrate 71.

There is no limitation to the number of the electronic components 76 incorporated in the substrate 70 of the above embodiments. For example, the substrate 70 may incorporate only one electronic component 76. For example, the substrate 70 may incorporate three or more electronic components 76.

In the semiconductor device 1 of the above embodiments, there is no limitation to the number of semiconductor chips 110 mounted on the wiring substrate 10.

In the above embodiments, a structure corresponding to part of the wiring substrates 10, 10A, and 10B is formed on both upper and lower surfaces of the supports 200 and 230. This, however, is not a limitation. For example, a structure corresponding to part of the wiring substrates 10, 10A, and 10B may be formed on only one surface of each of the supports 200 and 230.

### Clauses

This disclosure further encompasses the following embodiments.
1. A method for manufacturing a wiring substrate, the method including:
preparing a support;
forming a first wiring layer on the support;
forming an N number of insulating layers, including a second insulating layer that covers the first wiring layer, on the support, where N is a natural number greater than or equal to 1;
forming a cavity, exposing a part of the support, in the N number of insulating layers;
fixing an electronic component on the support exposed from the cavity;
filling the cavity with a filling insulating layer that covers the electronic component;
removing the support;
forming a first insulating layer on a surface of the second insulating layer that was in contact with the support; and
forming first via wiring extending through the first insulating film in a thickness direction and electrically connected to a first electrode of the electronic component, and a second wiring layer on a second surface of the first insulating layer opposite a first surface contacting the second insulating layer, in which the second wiring layer is electrically connected by the first via wiring to the first electrode.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate of a coreless type, the wiring substrate comprising:
a first insulating layer;
a first wiring layer formed on the first insulating layer;
an N number of insulating layers formed on a first surface of the first insulating layer and including a second insulating layer that covers the first wiring layer, wherein Nis a natural number greater than or equal to 1;
a cavity formed in the N number of insulating layers and exposing a part of the first surface of the first insulating layer;
an electronic component disposed in the cavity and including a first electrode covered by the first insulating layer;
a filling insulating layer with which the cavity is filled covering the electronic component;
first via wiring extending through the first insulating layer in a thickness direction and connected to the first electrode; and
a second wiring layer formed on a second surface of the first insulating layer opposite the first surface and electrically connected by the first via wiring to the first electrode,
wherein the cavity has an opening width that decreases toward the first insulating layer, and
the first via wiring has a diameter that decreases toward the electronic component.

2. The wiring substrate according to claim 1, wherein:
the first insulating layer includes a first projection projecting from the first surface of the first insulating layer into the cavity;
the first projection is located within the cavity and covers the first electrode; and
the first insulating layer is a single layer.

3. The wiring substrate according to claim 2, wherein:
the filling insulating layer covers a side surface of the electronic component together with a side surface of the first projection.

4. The wiring substrate according to claim 2, wherein:
the first via wiring extends through the first insulating layer together with the first projection from the second surface of the first insulating layer to the first electrode in the thickness direction and exposes from an upper surface of the first projection.

5. The wiring substrate according to claim 4, further comprising:
second via wiring extending through the first insulating layer in the thickness direction and connected to the first wiring layer; and
a third wiring layer formed on the second surface of the first insulating layer and electrically connected by the second via wiring to the first wiring layer, wherein
the second via wiring and the third wiring layer are located at positions separated from the cavity in plan view, and
the first via wiring extending from the second surface of the first insulating layer to the first electrode is longer than the second via wiring extending from the second surface of the first insulating layer to the first wiring layer.

6. The wiring substrate according to claim 1, wherein:
the first insulating layer includes
a first insulative resin defining the first surface, and
a second insulative resin arranged on the first surface of the first insulative resin and located within the cavity; and
the first via wiring extends through the first insulative resin and the second insulative resin in the thickness direction.

7. The wiring substrate according to claim 1, wherein:
the first insulating layer includes a second projection projecting from the first surface of the first insulating layer into the N number of insulating layers;
the first wiring layer is arranged on the second projection; and
the second insulating layer covers a side surface of the second projection.

8. The wiring substrate according to claim 7, further comprising:
second via wiring extending through the first insulating layer together with the second projection from the second surface of the first insulating layer to the first wiring layer in the thickness direction and connected to the first wiring layer; and
a third wiring layer formed on the second surface of the first insulating layer and electrically connected by the second via wiring to the first wiring layer, wherein
the second via wiring and the third wiring layer are located at positions separated from the cavity in plan view, and
the second via wiring extending from the second surface of the first insulating layer to the first wiring layer is longer than the first via wiring extending from the second surface of the first insulating layer to the first electrode.

9. The wiring substrate according to claim 1, further comprising:
second via wiring extending through the first insulating layer in the thickness direction and connected to the first wiring layer; and
a third wiring layer formed on the second surface of the first insulating layer and electrically connected by the second via wiring to the first wiring layer, wherein
the second via wiring and the third wiring layer are located at positions separated from the cavity in plan view,
the second via wiring has a diameter that decreases toward the first wiring layer, and
the diameter of the first via wiring is smaller than the diameter of the second via wiring.

10. The wiring substrate according to claim 1, further comprising:
a solder resist layer formed on the second surface of the first insulating layer and covering the second wiring layer;
third via wiring extending through the solder resist layer in the thickness direction and connected to the second wiring layer; and
a fourth wiring layer formed on a surface of the solder resist layer opposite a surface contacting the first insulating layer and electrically connected by the third via wiring to the second wiring layer,
wherein the third via wiring has a diameter that decreases toward the second wiring layer.

11. The wiring substrate according to claim 1, further comprising:
fourth via wiring extending through the second insulating layer in the thickness direction and connected to the first wiring layer; and
a fifth wiring layer formed on the second insulating layer and electrically connected by the fourth via wiring to the first wiring layer,
wherein the fourth via wiring has a diameter that decreases toward the first wiring layer.

12. The wiring substrate according to claim 1, wherein the electronic component includes a second electrode opposite the first electrode, the wiring substrate further comprising:
fifth via wiring extending through the filling insulating layer in the thickness direction and connected to the second electrode; and
a sixth wiring layer formed on the filling insulating layer and electrically connected by the fifth via wiring to the second electrode, wherein
the fifth via wiring has a diameter that decreases toward the second electrode, and
the diameter of the first via wiring is smaller than the diameter of the fifth via wiring.

13. A semiconductor device, comprising:
the wiring substrate according to claim 1;
a further substrate on which the wiring substrate is mounted; and
a semiconductor chip mounted on the wiring substrate at a side that is where the second wiring layer is located and is opposite the further substrate,
wherein the electronic component is defined as a first electronic component, and the further substrate incorporates a second electronic component electrically connected to the first electronic component.
